(19) United States
(12) Patent Application Publication
(10) Pub. No.: US 2025/0107379 A1
(43) Pub. Date: Mar. 27, 2025

(54) DISPLAY DEVICE AND METHOD FOR MANUFACTURING THE SAME

(71) Applicant: Samsung Display Co., Ltd., Yongin-si (KR)

(72) Inventor: CHOLONG WON, Yongin-si (KR)

(73) Assignee: Samsung Display Co., Ltd., Yongin-si (KR)

(21) Appl. No.: 18/625,426

(22) Filed: Apr. 3, 2024

(30) Foreign Application Priority Data
Sep. 26, 2023 (KR) 10-2023-0129483

(51) Int. Cl. H10K 59/179; H10K 59/12; H10K 59/40; H10K 102/00

(52) U.S. Cl. CPC H10K 59/179; H10K 59/1201; H10K 59/40; H10K 2102/311

(57) ABSTRACT

A display device includes a display module including a pixel, a signal line electrically connected to the pixel, and a signal pad contacting the signal line. The signal pad includes an insulating pattern disposed on the signal line, and a conductive pattern electrically connected to the signal line. The conductive pattern includes a first part including a mesh pattern, and a second part surrounding the first part. At least a portion of the first part is disposed on the insulating pattern.

### CROSS-REFERENCE TO RELATED APPLICATION(S)

This application claims priority to and benefits of Korean Patent Application No. 10-2023-0129483 under 35 U.S.C. § 119, filed on Sep. 26, 2023, in the Korean Intellectual Property Office, the entire contents of which are incorporated herein by reference.

### BACKGROUND

Embodiments relate to a pad region of a display device and a method for manufacturing a display device.

A display device includes a display region activated in response to an electrical signal. The display device may sense an input applied from the outside through a display region while displaying various images to be provided for a user.

The display device includes a display panel and a circuit board. The display panel may be connected to a main board through a circuit board. A driving chip may be mounted on the display panel.

### SUMMARY

Embodiments of the disclosure provide a display device improved in bonding reliability and a method for manufacturing the same.

According to an embodiment, a display device may include a display module that may include a pixel, a signal line electrically connected to the pixel, and a signal pad electrically connected to the signal line. The signal pad may include an insulating pattern disposed on the signal line, and a conductive pattern electrically connected to the signal line. The conductive pattern may include a first part including a mesh pattern, and a second part surrounding the first part. At least a portion of the first part may be disposed on the insulating pattern.

The conductive pattern may include a conductive material, and the insulating pattern may include a polymer.

The mesh pattern may include first mesh lines extending in a first direction, and disposed in a second direction intersecting the first direction, and second mesh lines extending in the second direction and disposed in the first direction while intersecting the first mesh lines.

The insulating pattern may include a plurality of insulating patterns, the first part may include a plurality of first parts, and each of the plurality of first parts may be disposed on a relevant insulating pattern among the plurality of insulating patterns.

The insulating pattern may include a plurality of insulating patterns, and the first part may be disposed on the plurality of insulating patterns.

The plurality of insulating patterns may be disposed in the first direction, each of the first mesh lines may intersect the plurality of insulating patterns, when viewed in a plan view, the second mesh lines may include a plurality of line groups, and each of the plurality of line groups may intersect a relevant insulating pattern among the plurality of insulating patterns, when viewed in a plan view.

The insulating pattern may include a plurality of insulating patterns, and the plurality of insulating patterns may be disposed in at least one of the first direction and the second direction.

The insulating pattern may have a semi-circular shape, when viewed in a cross-sectional view.

The display module may further include a pad insulating layer between the signal line and the conductive pattern, and the pad insulating layer may have a contact hole defined in the pad insulating layer, spaced apart from the insulating pattern, and overlapping a portion of the signal line.

The conductive pattern may contact the signal line through the contact hole, and the insulating pattern may be directly disposed on the pad insulating layer.

The pixel may include a light emitting element, a transistor electrically connected to the light emitting element, and including a semiconductor pattern and a gate overlapping the semiconductor pattern, an upper electrode disposed on the gate, and a plurality of conductive layers electrically connected to the transistor, disposed on the upper electrode, and disposed in mutually different layers. A portion, which is disposed under the conductive pattern, of the signal line and the gate or the upper electrode may include a same material, and the conductive pattern and at least one of the plurality of conductive layers may include a same material.

The signal pad may further include a lower conductive pattern disposed under the conductive pattern and contacting the signal line through the contact hole, and the insulating pattern may be between the lower conductive pattern and the conductive pattern.

The pixel may include a light emitting element, a transistor electrically connected to the light emitting element, and including a semiconductor pattern and a gate overlapping the semiconductor pattern, an upper electrode disposed on the gate, and a plurality of conductive layers electrically connected to the transistor, disposed on the upper electrode, and disposed in mutually different layers. A portion, which is disposed under the conductive pattern, of the signal line and the gate or the upper electrode may include a same material.

The lower conductive pattern and at least some conductive layers of the plurality of conductive layers may include a same material, and the conductive pattern and other conductive layers of the plurality of conductive layers, which are disposed on the at least some conductive layers, may include a same material.

The display module may further include a thin film encapsulation layer disposed on the pixel, and a sensing electrode disposed on the thin film encapsulation layer. The lower conductive pattern and at least one conductive layer of the plurality of conductive layers may include a same material, and the conductive pattern and the sensing electrode may include a same material.

The display module may further include a sensor insulating layer between the lower conductive pattern and the conductive pattern, and contacting the sensing electrode, and the conductive pattern may contact the lower conductive pattern through an upper contact hole defined in the sensor insulating layer.

According to an embodiment of the disclosure, a display device may include a display module that may include a pixel, a signal line electrically connected to the pixel, and a signal pad electrically connected to the signal line. The signal pad may include an insulating pattern disposed on the signal line, and a conductive pattern electrically connected to the signal line. At least a portion of the conductive pattern may have a form of a plurality of protrusions protruding from the insulating pattern, when viewed in a cross-sectional view.

The at least a portion of the conductive pattern may include first mesh lines extending in a first direction, and disposed in a second direction intersecting the first direction, and second mesh lines extending in the second direction and disposed in the first direction while crossing the first mesh lines. The first mesh lines may provide the form of the plurality of protrusions, when viewed in a cross-sectional view in the first direction, and the second mesh lines may provide the form of the plurality of protrusions, when viewed in a cross-sectional view in the second direction.

According to an embodiment of the disclosure, a method for manufacturing a display device may include providing a preliminary signal pad including an insulating pattern, depositing a preliminary conductive pattern on the preliminary signal pad, and patterning the preliminary conductive pattern to form a conductive pattern at least partially including a mesh pattern. At least a portion of the mesh pattern may be disposed on the insulating pattern.

The patterning of the preliminary conductive pattern may include forming a photoresist pattern on the preliminary conductive pattern, etching a portion of the preliminary conductive pattern exposed from the photoresist pattern, and removing the photoresist pattern to form a signal pad.

### BRIEF DESCRIPTION OF THE DRAWINGS

The above and other aspects and features of the disclosure will become apparent by describing in detail embodiments thereof with reference to the accompanying drawings.

FIG. 1 is a schematic perspective view illustrating a display device according to an embodiment of the disclosure.

FIGS. 2A and 2B are exploded schematic perspective views of a display device according to an embodiment of the disclosure.

FIG. 3 is a schematic cross-sectional view illustrating a display module according to an embodiment of the disclosure.

FIG. 4 is a schematic plan view illustrating a display panel according to an embodiment of the disclosure.

FIG. 5 is a schematic cross-sectional view of a pixel according to an embodiment of the disclosure.

FIG. 6A is a schematic cross-sectional view of an input sensor according to an embodiment of the disclosure.

FIG. 6B is a schematic plan view of an input sensor according to an embodiment of the disclosure.

FIG. 6C is a schematic cross-sectional view of a bridge pattern of an input sensor according to an embodiment of the disclosure.

FIG. 7 is an enlarged exploded schematic perspective view illustrating a display device according to an embodiment of the disclosure;

FIG. 8A is a schematic plan view illustrating a pad region according to an embodiment of the disclosure.

FIG. 8B is an enlarged schematic plan view illustrating a portion of a pad region according to an embodiment of the disclosure.

FIGS. 9A and 9B are schematic cross-sectional views corresponding to FIG. 8A.

FIG. 10 is a schematic cross-sectional view illustrating a bonding structure of a display device according to an embodiment of the disclosure;

FIG. 11A is a schematic plan view illustrating a pad region according to an embodiment of the disclosure.

FIG. 11B is an enlarged schematic plan view illustrating a portion of a pad region according to an embodiment of the disclosure.

FIG. 12 is a schematic plan view illustrating a pad region according to an embodiment of the disclosure.

FIG. 13 is a schematic cross-sectional view corresponding to FIG. 12.

FIG. 14 is a schematic plan view illustrating a pad region according to an embodiment of the disclosure.

FIGS. 15A and 15B are schematic cross-sectional views corresponding to FIG. 14.

FIG. 16 is a schematic plan view illustrating a pad region according to an embodiment of the disclosure.

FIGS. 17A and 17B are schematic cross-sectional views corresponding to FIG. 16.

FIGS. 18A, 18B, 18C, 18D, and 18E are schematic cross-sectional views illustrating some steps in a method for manufacturing a display device according to an embodiment of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the specification, the expression that a first component (or region, layer, part, portion, etc.) is “on”, “connected to”, or “coupled to” a second component means that the first component is directly on, connected to, or coupled to the second component or means that a third component is interposed therebetween.

The same reference numeral will be assigned to the same component. In addition, in drawings, thicknesses, proportions, and dimensions of components may be exaggerated to describe the technical features effectively.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Although the terms “first”, “second”, etc. may be used to describe various components, the components should not be construed as being limited by the terms. The terms are only used to distinguish one component from another component. For example, without departing from the scope and spirit of the disclosure, a first component may be referred to as a second component, and similarly, the second component may be referred to as the first component. The singular forms are intended to include the plural forms unless the context clearly indicates otherwise.

In addition, the terms “under”, “at a lower portion”, “above”, “an upper portion” are used to describe the relationship between components illustrated in drawings. The terms are relative and are described with reference to a direction indicated in the drawing.

It will be further understood that the terms “comprises,” “comprising,” “includes,” or “including,” or “having” specify the presence of stated features, numbers, steps, operations, components, parts, or the combination thereof, but do not preclude the presence or addition of one or more other features, numbers, steps, operations, components, components, and/or the combination thereof.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as “not overlapping” or “to not overlap” another element, this may include that the elements are spaced apart from each other, offset from each other, or set aside from each other or any other suitable term as would be appreciated and understood by those of ordinary skill in the art.

Unless otherwise defined or implied, all terms (including technical terms and scientific terms) used in the specification have the same meaning as commonly understood by one skilled in the art to which the disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

“About,” “approximately,” “substantially,” and the like are inclusive of the stated value and mean within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the term “about” may also be used to indicate relative location (e.g., rotation “about” an axis).

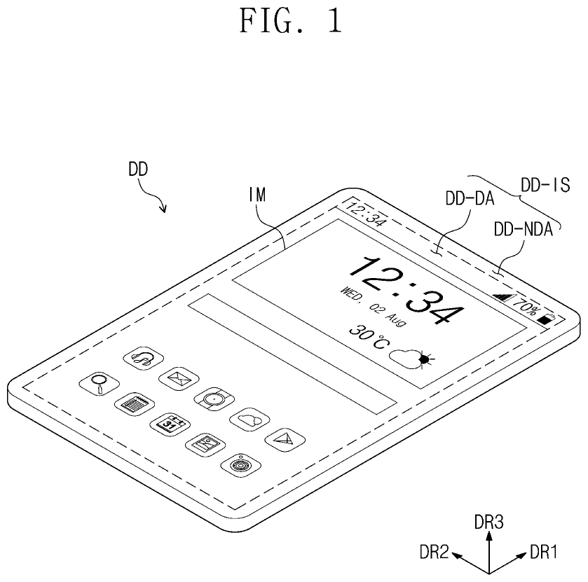

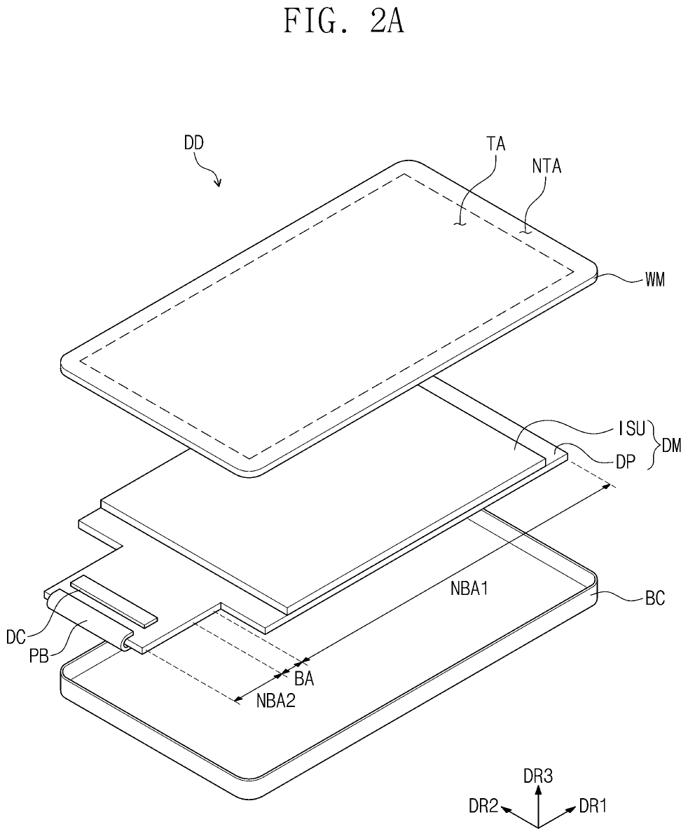

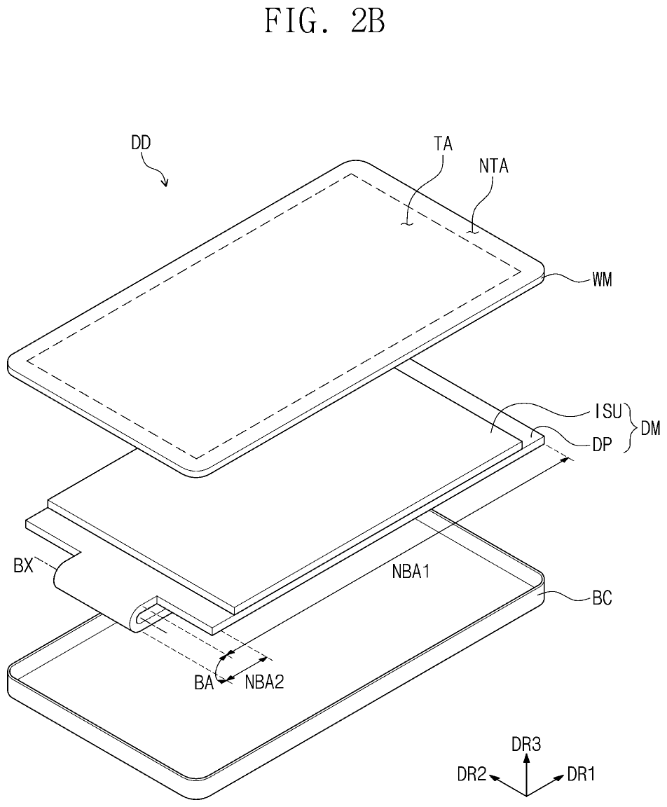

FIG. 1 is a schematic perspective view illustrating a display device DD according to an embodiment of the disclosure; FIGS. 2A and 2B are exploded schematic perspective views of the display device DD according to an embodiment of the disclosure.

For example, FIG. 2B illustrates a state in which a bending region BA illustrated in FIG. 2A is bent.

Referring to FIG. 1, according to this specification, a cellular terminal is illustrated as an example of the display device DD. However, the display device DD may include a large-size display device, such as a television or a monitor, or a small or medium-size display device, such as a tablet, a vehicle navigation, a game console, or a smart watch.

The display device DD is in the shape of a rectangle having a longer side extending in a first direction DR1 and a shorter side extending in a second direction DR2 crossing (intersecting) the first direction DR1, when viewed in a plan view. However, an embodiment is not limited thereto, and the display device DD may have various shapes, such as a circle shape or a polygon shape, when viewed in a plan view.

Hereinafter, a direction substantially perpendicular to a plane defined by the first direction DR1 and the second direction DR2 is defined as a third direction DR3. In the specification, the meaning of “when viewed in a plan view” may refer to “when viewed in the third direction DR3”.

The display device DD may be rigid or flexible. The “flexible characteristic” refers to a bendable characteristic, and a flexible structure may include structures ranging from a fully folded structure to a structure bent by a level of several nanometers. For example, the flexible display device DD may include a curved display device, a rollable display device, or a foldable display device.

The display device DD may display an image IM through a display surface DD-IS. The drawing illustrates icon images by way of example of the image IM. The display surface DD-IS may be parallel to a plane defined by the first direction DR1 and the second direction DR2.

The display surface DD-IS may include a display region DD-DA to display the image IM and a non-display region DD-NDA adjacent to the display region DD-DA. The non-display region DD-NDA may be a region in which the image IM is not displayed. However, the disclosure is not limited thereto. The non-display region DD-NDA may be adjacent to any side of the display region DD-DA or may be omitted.

Referring to FIGS. 2A and 2B, the display device DD may include a window WM, a display module DM, and a receiving member BC.

The window WM may be disposed on the display module DM, and may transmit an image provided from the display module DM to the outside. The window WM may include a transmission region TA and a non-transmission region NTA. The transmission region TA may have the form which overlaps the display region DD-DA illustrated in FIG. 1 and corresponds to the display region DD-DA. Although not illustrated, the window WM may include a base layer and functional layers disposed on the base layer. The functional layers may include a protective layer and an anti-fingerprint layer. The base layer of the window WM may include at least one of glass, sapphire, and plastic. The base layer of the window WM may include an optically transparent material. For example, the base layer of the window WM may include a glass or plastic film or may include a glass substrate and a plastic film coupled by an adhesive.

The non-transmission region NTA may have the form which overlaps the non-display region DD-NDA illustrated in FIG. 1 and corresponds to the non-display region DD-NDA. The non-transmission region NTA may have a light transmittance lower than a light transmittance of the transmission region TA. The non-transmission region NTA may be defined by a bezel pattern provided in a partial region of the base layer of the window WM, and the region, in which the bezel pattern is not disposed, is defined as the transmission region TA. However, the disclosure is not limited thereto, and the non-transmission region NTA may be omitted.

Although not illustrated, the anti-reflective layer may be disposed between the window WM and the display module DM. The anti-reflective layer may reduce the reflectance of external light incident from the outside of the display device DD. The anti-reflective layer may include color filters. The color filters may have a specific array. For example, the color filters may be arranged (disposed) based on light emitting colors of pixels included in a display panel DP to be described below. In addition, the anti-reflective layer may further include a black matrix adjacent to the color filters.

According to an embodiment of the disclosure, the display module DM may include the display panel DP and an input sensor ISU.

The display panel DP may include a liquid crystal display panel, an electrophoretic display panel, a microelectromechanical system display panel, an electrowetting display panel, an organic light emitting display panel, an inorganic light emitting display panel, and/or a quantum dot light emitting display panel. However, the disclosure is not limited thereto. Hereinafter, the display panel DP will be described as an organic light emitting display panel.

The input sensor ISU may include any of a capacitive sensor, an optical sensor, an ultrasonic sensor, and/or an electromagnetic induction sensor. The input sensor ISU may be formed on the display panel DP through a subsequent processor. As another example, the input sensor ISU may be fabricated separately and may be bonded onto the display panel DP through an adhesive layer.

The display device DD may further include a driving chip DC disposed on the display panel DP. The display device DD may further include a circuit board PB disposed on the display panel DP. According to an embodiment, the circuit board PB may be a flexible circuit board, but the disclosure is not limited thereto. For example, the circuit board PB may be rigid. The circuit board PB may electrically connect the display panel DP to a main circuit board.

The driving chip DC may include a driving element, such as a data driving circuit, to drive a pixel of the display panel DP. Although FIG. 2A illustrates that the driving chip DC is mounted on the display panel DP, the disclosure is not limited thereto. For example, the driving chip DC may be mounted on the circuit board PB. According to an embodiment, the driving chip DC and the circuit board PB directly mounted on the display panel DP may be collectively referred to as an electronic compartment. Hereinafter, the bonding structure between the display panel DP and the circuit board PB may be identically applied to another electronic component, such as the driving chip DC, other than the circuit board PB.

The display panel DP may include the bending region BA, a first non-bending region NBA1, and a second non-bending region NBA2. The first non-bending region NBA1 and the second non-bending region NBA2 may be spaced apart from each other. The bending region BA may be between the first non-bending region NBA1 and the second non-bending region NBA2.

The bending region BA may be defined as a region in which the display panel DP is bent in a virtual bending axis BX extending in the second direction DR2. The first non-bending region NBA1 may be defined as a region overlapping the transmission region TA, and the second non-bending region NBA2 may be defined as a region connected to the circuit board PB. In case that the bending region BA is bent about the virtual bending axis BX, the circuit board PB and the driving chip DC may be bent toward the rear surface of the display panel DP and may be disposed under the rear surface of the display panel DP. Although not illustrated, additional components may be disposed to compensate for the step difference between the circuit board PB and the rear surface of the display panel DP, which is made due to the bending region BA.

According to an embodiment, the width of the first non-bending region NBA1 in the second direction DR2 may be greater than the width of the bending region BA and the second non-bending region NBA2. However, the disclosure is not limited thereto. The width of the bending region BA in the second direction DR2 may be provided to be more reduced from the first non-bending region NBA1 to the second non-bending region NBA2, and the disclosure is not limited to any one embodiment.

As illustrated in FIG. 2B, as a portion of the display panel DP is bent, the circuit board PB electrically bonded to the display panel DP may be disposed on the rear surface of the display panel DP.

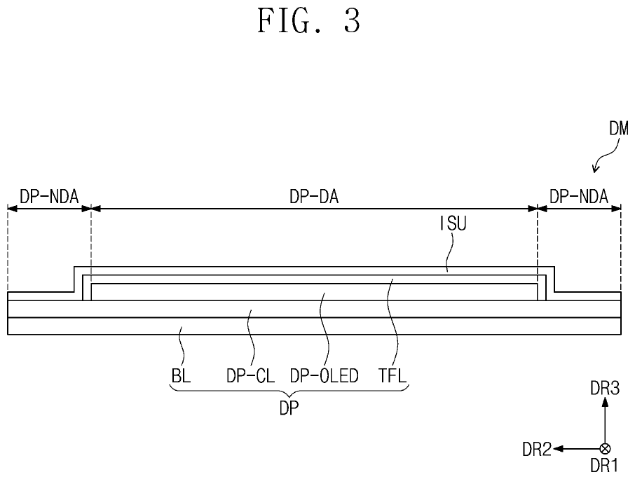

The receiving member BC may receive the display module DM and may be coupled to the window WM. The circuit board PB may be disposed at an end portion of the display panel DP, and may be electrically connected to a circuit element layer DP-CL to be described with reference to FIG. 3. Although not illustrated, the display device DD may further include a main board, electronic modules, a camera module, or a power module mounted on the main board.

Although the above description has been made in that the cellular phone serves as the display device DD, various types of display devices may be provided as noted above, as long as the display device DD includes at least electronic components bonded to each other. The display panel DP and the driving chip DC mounted on the display panel DP may correspond to mutually different electronic components, and the display device DD may be provided using the display panel DP and the driving chip DC. The display panel DP and the circuit board PB connected on the display panel DP may correspond to mutually different electronic components, and the display device DD may be provided only using the display panel DP and the circuit board PB. In addition, the display device DD may be provided only using the main board and the electronic module mounted on the main board. Hereinafter, the display device DD according to the disclosure will be described while focusing on the bonding structure between the display panel DP and the driving chip DC mounted on the display panel DP.

FIG. 3 is a schematic cross-sectional view illustrating the display module DM according to an embodiment of the disclosure.

Referring to FIG. 3, the display panel DP may include a base layer BL, the circuit element layer DP-CL disposed on the base layer BL, a display element layer DP-OLED, and an upper insulating layer TFL. The input sensor ISU may be disposed on the upper insulating layer TFL.

The display panel DP may include a display region DP-DA and a non-display region DP-NDA. The display region DP-DA of the display panel DP may correspond to the display region DD-DA illustrated in FIG. 1 or the transmission region TA illustrated in FIG. 2A. The non-display region DP-NDA may correspond to the non-display region DD-NDA illustrated in FIG. 1 or the non-transmission region NTA illustrated in FIG. 2A.

The base layer BL may include at least one plastic film. The base layer BL may serve as a flexible substrate, and may include a plastic substrate, a glass substrate, a metal substrate, and/or an organic/inorganic composite substrate.

The circuit element layer DP-CL may include at least one intermediate insulating layer and a circuit element. The intermediate insulating layer may include at least one intermediate inorganic layer and at least one intermediate organic layer. The circuit element may include signal lines and a driving circuit of the pixel. An insulating layer, a semiconductor layer, and the conductive layer may be formed through processes, such as a coating process, or a deposition process. Thereafter, the insulating layer, the semiconductor layer, and the conductive layer may be selectively patterned through photolithography and etching processes. The semiconductor pattern, the conductive pattern, and the signal line may be formed through the processes. The patterns formed in the same layer may be formed through the same process. In this specification, that patterns are formed through the same process refers to that the patterns may include the same material and have the same stack structure.

The display element layer DP-OLED may further include light emitting elements. The display element layer DP-OLED may further include an organic layer such as a pixel defining film.

The upper insulating layer TFL may seal the display element layer DP-OLED. The upper insulating layer TFL may be disposed on the display element layer DP-OLED. The upper insulating layer TFL according to an embodiment may overlap the display region DP-DA and the non-display region DP-NDA. The upper insulating layer TFL may overlap at least a portion of the non-display region DP-NDA. For example, the upper insulating layer TFL may include a thin film encapsulation layer. The thin film encapsulation layer may include a stack structure of an inorganic layer, an organic layer, and an inorganic layer. The upper insulating layer TFL may protect the display element layer DP-OLED from foreign substances such as moisture, oxygen, and dust particles. However, the disclosure is not limited thereto. The upper insulating layer TFL may further include an additional insulating layer in addition to the thin film encapsulation layer. For example, the upper insulating layer TFL may further include an optical insulating layer to control a refractive index.

According to an embodiment of the disclosure, an encapsulation substrate may be provided in place of the upper insulating layer TFL. In this case, the encapsulation substrate may face the base layer BL, and the circuit element layer DP-CL and the display element layer DP-OLED may be between the encapsulation substrate and the base layer BL.

The input sensor ISU may be directly disposed on the display panel DP. In the specification “component “A” is directly disposed on component “B” refers to that no separate layer is disposed between component “A” and component “B”. According to an embodiment, the input sensor ISU may be manufactured through a process subsequent to the process for the display panel DP. However, the technical spirit of the disclosure is not limited thereto, and the input sensor ISU, which is provided as an individual panel, may be coupled to the display panel DP through an adhesive layer. For example, the input sensor ISU may be omitted.

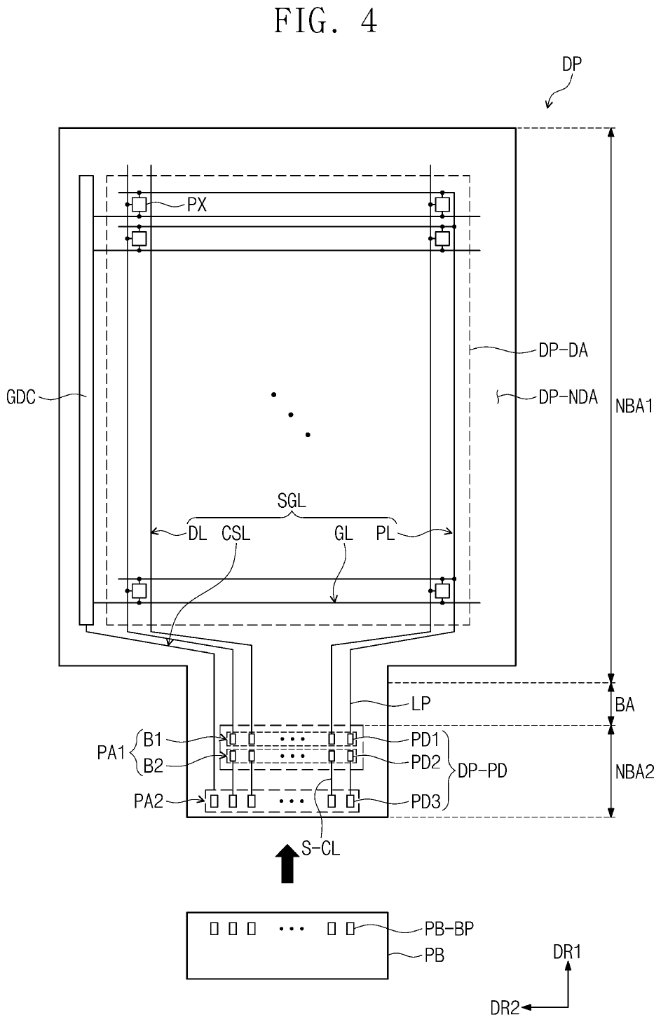

FIG. 4 is a schematic plan view illustrating the display panel DP according to an embodiment of the disclosure.

Referring to FIG. 4, the display panel DP may include pixels PX, a gate driving circuit GDC, signal lines SGL, and signal pads DP-PD.

The pixels PX may be disposed in the display region DP-DA. Each of the pixels PX may include a light emitting element and a pixel driving circuit connected thereto. According to an embodiment, the light emitting element may be an organic light emitting element. The gate driving circuit GDC may sequentially output gate signals to gate lines GL to be described later. A transistor of the gate driving circuit GDC may be formed through a process the same as a process, which is a process for the transistor of the pixel PX, such as a low temperature polycrystalline silicon (LTPS) process or a low temperature polycrystalline oxide (LTPO) process. The display panel DP may further include another driving circuit to drive an emission control signal to the pixels PX.

The signal lines SGL may include the gate lines GL, data lines DL, a power line PL, and a control signal line CSL. The gate lines GL may be connected to relevant pixels PX among the pixels PX, respectively, and the data lines DL may be connected to relevant pixels PX among the pixels PX, respectively. The power line PL may be connected to the pixels PX. The control signal line CSL may provide control signals to a scan driving circuit.

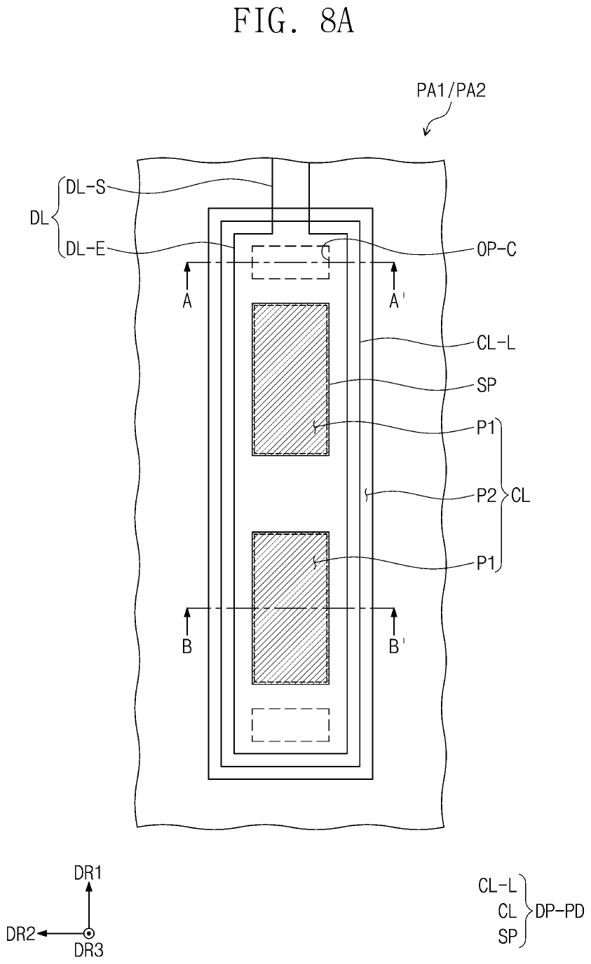

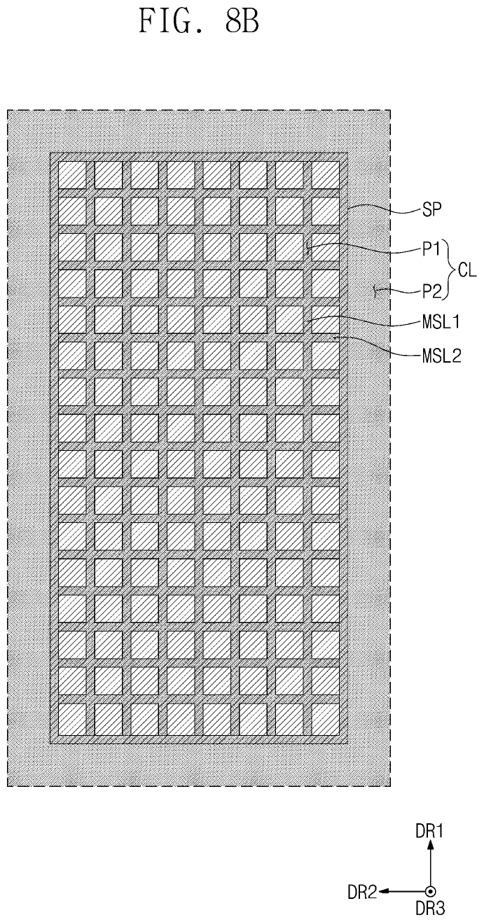

The signal lines SGL may overlap the display region DP-DA and the non-display region DP-NDA. Each of the signal lines SGL may include a line part LP. Although not illustrated, the signal lines SGL may further include a pad part. The line part LP may overlap the display region DP-DA and the non-display region DP-NDA. The pad part may be connected to an end portion of the line part LP. The connection between the pad part and the line part LP will be described in detail in FIG. 8A.

The signal pads DP-PD may include first pads PD1, second pads PD2, and third pads PD3. A region, in which the first and second pads PD1 and PD2 are disposed, may be defined as a first pad region PA1, and a region, in which the third pads PD3 are disposed, may be defined as a second pad region PA2.

The first pad region PA1 may be a region overlapping the driving chip DC of FIG. 2A, and the second pad region PA2 may be a region overlapping the circuit board PB. The first pad region PA1 may include a first region B1 in which the first pads PD1 are disposed and a second region B2 in which the second pads PD2 are disposed. The first pad region PA1 and the second pad region PA2 may be disposed in the non-display region DP-NDA. The first pad region PA1 and the second pad region PA2 may be spaced apart from each other in the first direction DR1. Although one row of pads disposed in the first pad region PA1 are provided by way of example, the disclosure is not limited thereto. For example, multiple pad rows may be disposed in the first pad region PA1.

Each of the first pads PD1 may be connected to a relevant data line DL among the data lines DL. Although not illustrated, the first pads PD1 and the second pads PD2 may be electrically connected to each other. The second pads PD2 may be connected to the third pads PD3 through connection signal lines SCLn.

The circuit board PB may include substrate bump electrodes PB-BP. The substrate bump electrodes PB-BP may be arranged in the second direction DR2. The substrate bump electrodes PB-BP of the circuit board PB may contact and connect to the third pads PD3 of the second pad region PA2.

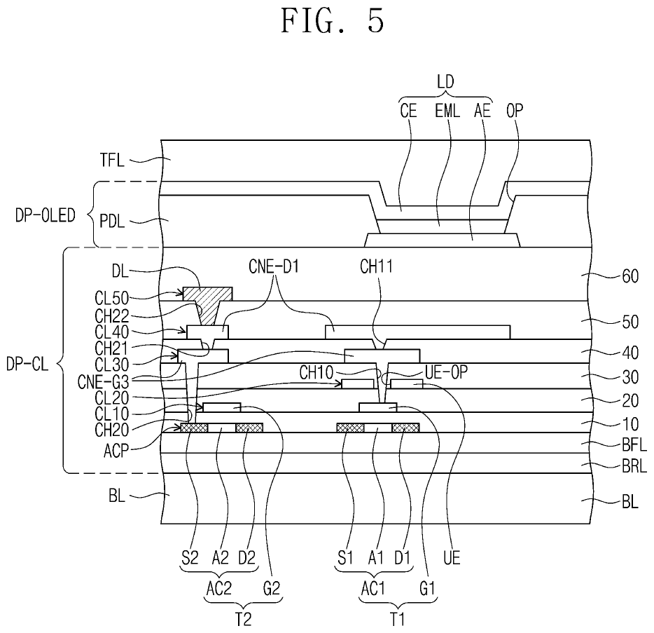

FIG. 5 is a schematic cross-sectional view illustrating the display panel DP according to an embodiment of the disclosure.

Referring to FIG. 5, the display panel DP may include the base layer BL, the circuit element layer DP-CL disposed on the base layer BL, the display element layer DP-OLED, and the upper insulating layer TFL. A first transistor T1 and a second transistor T2 may be disposed as the driving circuit of the pixel by way of example.

Multiple insulating layers are disposed on a top surface of the base layer BL. The insulating layers may include a barrier layer BRL and a buffer layer BFL. The insulating layers may further include a first insulating layer 10 to a sixth insulating layer 60. The barrier layer BRL may prevent foreign substances from being infiltrated from the outside. The barrier layer BRL may include at least one of a silicon oxide layer and a silicon nitride layer. The silicon oxide layer may include multiple silicon oxide layers and the silicon nitride layer may include multiple silicon nitride layers, and the silicon oxide layers and the silicon nitride layers may be stacked on each other.

The buffer layer BFL may improve a coupling force between the base layer BL and the semiconductor pattern and/or the conductive pattern. The barrier layer BRL may include at least one of a silicon oxide layer and a silicon nitride layer. The silicon oxide layer and the silicon nitride layer may be stacked on each other.

A semiconductor pattern ACP may be disposed on the buffer layer BFL. The semiconductor pattern may include an amorphous or crystalline silicon semiconductor or a metal oxide semiconductor. As illustrated in FIG. 5, the semiconductor pattern ACP may include a first semiconductor region AC1 and a second semiconductor region AC2. The first semiconductor region AC1 may include a source region S1, a channel region A1, and a drain region D1 of the first transistor T1, and the second semiconductor region AC2 may include a source region S2, a channel region A2, and a drain region D2 of the second transistor T2. According to an embodiment, the first and second transistors T1 and T2 may include different semiconductors. The second transistor T2 may include a material different from that of the first semiconductor region AC1, and may be disposed in a different layer.

The first insulating layer 10 may be disposed on the buffer layer BFL. The first insulating layer 10 may cover the semiconductor pattern ACP. The first insulating layer 10 may be an inorganic layer, but the disclosure is not limited thereto. A first conductive layer CL10 may be disposed on the first insulating layer 10. The first conductive layer CL10 may include multiple conductive patterns. The first conductive layer CL10 may include a gate G1 of the first transistor T1 and a gate G2 of the second transistor T2. The first conductive layer CL10 may include at least one of molybdenum (Mo) having excellent heat resistance, an alloy containing molybdenum (Mo), titanium (Ti), and the alloy containing titanium, but the disclosure is not limited thereto. The first conductive layer CL10 may have a single-layer structure or a multi-layer structure.

A second insulating layer 20, which covers the first conductive layer CL10, may be disposed on the first insulating layer 10. The second insulating layer 20 may be an inorganic layer, but the disclosure is not limited thereto. A second conductive layer CL20 may be disposed on the second insulating layer 20. The second conductive layer CL20 may include multiple conductive patterns. The second conductive layer CL20 may include an upper electrode UE. The upper electrode UE may overlap the gate G1 of the first transistor T1, and an opening UE-OP may be formed. The upper electrode UE and the gate G1 of the first transistor T1, which overlap each other, may define a capacitor.

A third insulating layer 30, which covers the second conductive layer CL20, may be disposed on the second insulating layer 20. The third insulating layer 30 may be an inorganic layer, but the disclosure is not limited thereto. A third conductive layer CL30 may be disposed on the third insulating layer 30. The third conductive layer CL30 may include conductive patterns. The third conductive layer CL30 may include connection electrodes CNE-G3. A connection electrode CNE-G3 may be connected to the gate G1 of the first transistor T1 through a contact hole CH10 formed through the second insulating layer 20 and the third insulating layer 30. The contact hole CH10 may pass through the opening UE-OP. Another connection electrode CNE-G3 may be connected to the source region S2 of the second transistor T2 through a contact hole CH20 formed through the first insulating layer 10, the second insulating layer 20, and the third insulating layer 30. The third conductive layer CL30 may further include multiple connection electrodes (not illustrated).

The fourth insulating layer 40, which covers the third conductive layer CL30, may be disposed on the third insulating layer 30. The fourth insulating layer 40 may be an inorganic layer, but the disclosure is not limited thereto. A fourth conductive layer CL40 may be disposed on the fourth insulating layer 40. The fourth conductive layer CL40 may include multiple conductive patterns. The fourth conductive layer CL40 may include connection electrodes CNE-D1. The connection electrodes CNE-D1 may be connected to corresponding connection electrodes CNE-G3 through contact holes CH11 and CH21 penetrating the fourth insulating layer 40, respectively. The fourth conductive layer CL40 may further include multiple connection electrodes (not illustrated).

The fifth insulating layer 50, which covers the fourth conductive layer CL40, may be disposed on the fourth insulating layer 40. The fifth insulating layer 50 may be an inorganic layer, but the disclosure is not limited thereto. A fifth conductive layer CL50 may be disposed on the fifth insulating layer 50. The fifth conductive layer CL50 may include multiple conductive patterns. According to an embodiment, the fifth conductive layer CL50 may include the data line DL. The data line DL may be connected to a corresponding the connection electrode CNE-D1 through a contact hole CH22 formed through the fifth insulating layer 50. The fifth conductive layer CL50 may further include multiple connection electrodes (not illustrated).

The sixth insulating layer 60, which covers the fifth conductive layer CL50, may be disposed on the fifth insulating layer 50. The sixth insulating layer 60 may be an organic layer, but the disclosure is not limited thereto. A light emitting element LD may be disposed on the sixth insulating layer 60. A first electrode AE of the light emitting element LD may be disposed on the sixth insulating layer 60. The first electrode AE may be an anode, and a pixel defining film PDL is disposed on the sixth insulating layer 60.

An opening OP of the pixel defining film PDL may expose at least a portion of the first electrode AE. The opening OP of the pixel defining layer film may define a light emitting region. A light emitting layer EML may be disposed on the first electrode AE. Although the patterned light emitting layer EML is illustrated according to an embodiment, the light emitting layer EML may be commonly disposed in the plurality of pixels PX (see FIG. 4). The commonly disposed light emitting layer EML may generate white light or blue light. In addition, the light emitting layer EML may have a multi-layer structure.

Although not illustrated, a hole transport layer may be further disposed between the first electrode AE and the light emitting layer EML. A hole injection layer may be between the hole transport layer and the first electrode AE. The hole transport layer or the hole injection layer may be commonly disposed in the pixels PX (refer to FIG. 4).

A second electrode CE may be disposed on the light emitting layer EML. Although not illustrated, an electron transport layer may be further disposed between the second electrode CE and the light emitting layer EML. An electron injection layer may be between the electron transport layer and the second electrode CE. The electron transport layer or the electron injection layer may be commonly disposed in the pixels PX (refer to FIG. 4).

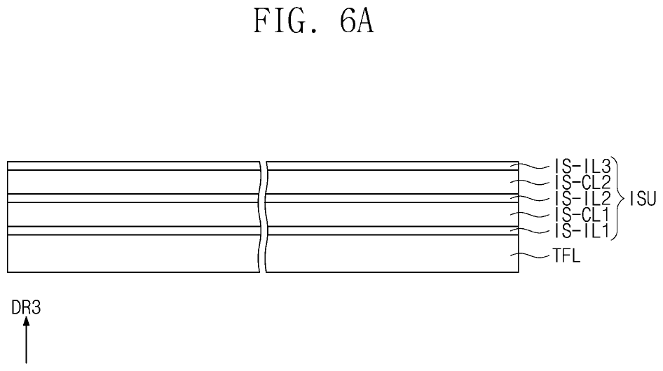

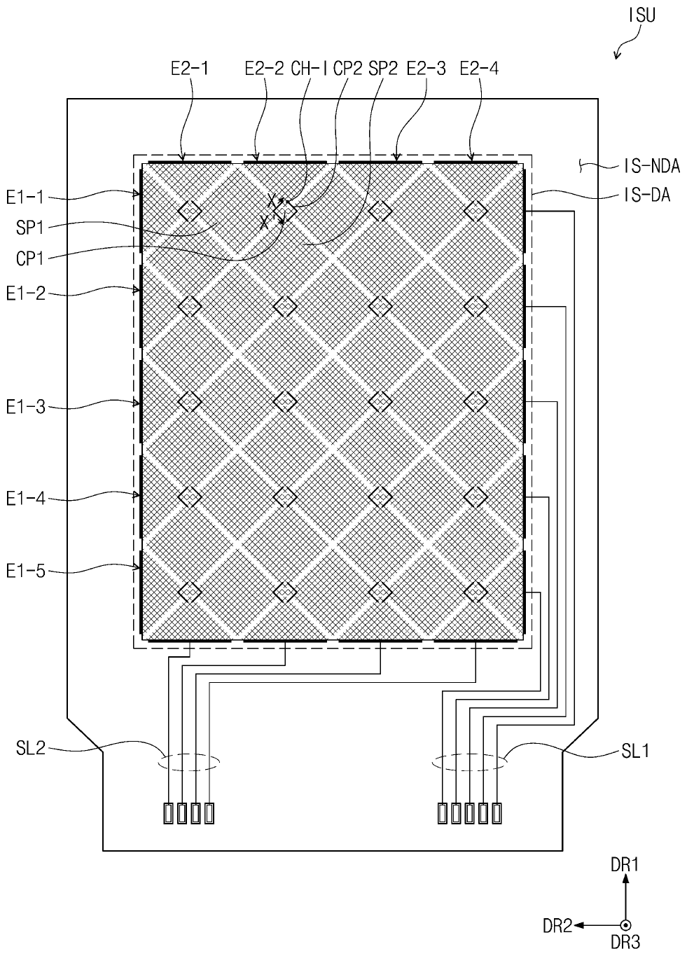

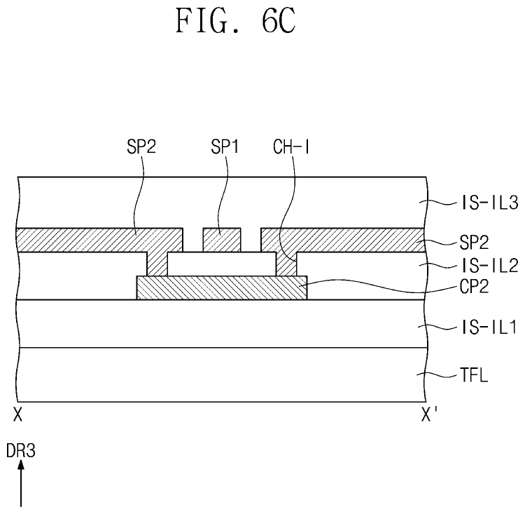

FIG. 6A is a schematic cross-sectional view of the input sensor ISU according to an embodiment of the disclosure. FIG. 6B is a schematic plan view of the input sensor ISU according to an embodiment of the disclosure. FIG. 6C is a cross-sectional view of a bridge pattern of the input sensor ISU according to an embodiment of the disclosure.

The input sensor ISU may include a first insulating layer (hereinafter, referred to as a “first sensing insulating layer”) IS-IL1, a first conductive pattern layer IS-CL1, a second insulating layer (hereinafter, referred to as a “second sensing insulating layer”) IS-IL2, a second conductive pattern layer IS-CL2, and a third insulating layer (hereinafter, referred to as a third sensing insulating layer) IS-IL3. The first sensing insulating layer IS-IL1 may be directly disposed on the upper insulating layer TFL.

According to an embodiment of the disclosure, the first sensing insulating layer IS-IL1 and/or the third sensing insulating layer IS-IL3 may be omitted. In case that the first sensing insulating layer IS-IL1 is omitted, the first conductive pattern layer IS-CL1 may be disposed on the uppermost insulating layer of the upper insulating layer TFL The third sensing insulating layer IS-IL3 may be replaced with an adhesive layer or an insulating layer of an anti-reflective member disposed on the input sensor ISU.

The first conductive pattern layer IS-CL1 may include first conductive patterns, and the second conductive pattern layer IS-CL2 may include second conductive patterns. Hereinafter, the first conductive pattern layer IS-CL1 and the first conductive patterns are assigned with the same reference numerals, and the second conductive pattern layer IS-CL2 and the second conductive patterns are assigned with the same reference numerals.

Each of the first conductive patterns IS-CL1 and the second conductive patterns IS-CL2 may have a single layer structure or the structure (multi-layer structure) of multiple layers stacked in the third direction DR3. The conductive patterns in the multi-layer structure may include at least two of transparent conductive layers and metal layers. The conductive patterns in the multi-layer structure may include metal layers including mutually different metals. The transparent conductive layer may include at least one of indium tin oxide (ITO), indium zinc oxide (IZO), zinc oxide (ZnO), indium tin oxide (ITZO), PEDOT, metal nanowires, and graphene. The metal layer may include at least one of molybdenum (Mo), silver (Ag), titanium (Ti), copper (Cu), aluminum (Al), and the alloys thereof. The details of the stack structure of each of the first conductive pattern layer IS-CL1 and the second conductive pattern layer IS-CL2 will be described later.

According to an embodiment, each of the first sensing insulating layer IS-IL1, the second sensing insulating layer IS-IL2, and the third sensing insulating layer IS-IL3 may include at least one of an inorganic layer and an organic layer. According to an embodiment, the first sensing insulating layer IS-IL1, the second sensing insulating layer IS-IL2, and the third sensing insulating layer IS-IL3 may include an inorganic layer. The inorganic layer may include at least one of silicon oxide, silicon nitride, and silicon oxynitride.

According to an embodiment, at least one of the first sensing insulating layer IS-IL1, the second sensing insulating layer IS-IL2, and the third sensing insulating layer IS-IL3 may include an organic layer. For example, the third sensing insulating layer IS-IL3 may include an organic layer. The organic layer may include at least one of an acrylic resin, a methacryl resin, polyisoprene, a vinyl resin, an epoxy resin, a urethane resin, a cellulose resin, a siloxane resin, a polyimide resin, a polyamide resin, and a perylene resin.

Referring to FIGS. 6B and 6C, the input sensor ISU may include a sensing region IS-DA and a non-sensing region IS-NDA adjacent to the sensing region IS-DA. The sensing region IS-DA and the non-sensing region IS-NDA may correspond to the display region DP-DA and the non-display region DP-NDA illustrated in FIG. 4, respectively.

The input sensor ISU may include sensing electrodes disposed in the sensing region IS-DA. The sensing electrodes may include first sensing electrodes (hereinafter referred to as “first electrodes”) E1-1 to E1-5, and second sensing electrodes (hereinafter referred to as “second electrodes”) E2-1 to E2-4, which insulate and cross each other The input sensor ISU includes first signal lines SL1, which are disposed in the non-sensing region IS-NDA and electrically connected to the first electrodes E1-1 to E1-5, and second signal lines SL2 which are electrically connected to the second electrodes E2-1 to E2-4. The first electrodes E1-1 to E1-5, the second electrodes E2-1 to E2-4, the first signal lines SL1, and the second signal lines SL2 may be defined through a combination of the first conductive patterns IS-CL1 and the second conductive patterns IS-CL2 described with reference to FIG. 6A.

Each of the first electrodes E1-1 to E1-5 and the second electrodes E2-1 to E2-4 may include multiple conductive lines crossing each other. The conductive lines may define multiple openings, and each of the first electrodes E1-1 to E1-5 and the second electrodes E2-1 to E2-4 may have a mesh shape. Each of the plurality of openings may be defined to correspond to the opening OP of the pixel defining film PDL illustrated in FIG. 5.

Any of the first electrodes E1-1 to E1-5 and the second electrodes E2-1 to E2-4 may have an integral shape. According to an embodiment, the first electrodes E1-1 to E1-5 having the integral shape are provided by way of example. The first electrodes E1-1 to E1-5 may include sensing parts SP1 and intermediate parts CP1. The portions of the second conductive patterns IS-CL2 described above may correspond to the first electrodes E1-1 to E1-5.

Each of the second electrodes E2-1 to E2-4 may include sensing patterns SP2 and bridge patterns CP2 (or connection patterns). As illustrated in FIGS. 6B and 6C, two adjacent sensing patterns SP2 may be connected to two bridge patterns CP2 through a contact hole CH-I formed through the second sensing insulating layer IS-IL2, but the number of bridge patterns is not limited thereto. Some of the second conductive patterns IS-CL2 described above may correspond to the sensing patterns SP2. Some of the first conductive patterns IS-CL1 described above may correspond to the bridge patterns CP2.

According to an embodiment, the bridge patterns CP2 may be formed from the first conductive patterns IS-CL1 illustrated in FIG. 6A, and the first electrodes E1-1 to E1-5 and the sensing patterns SP2 may be formed from the second conductive patterns IS-CL2, but the disclosure is not limited thereto. The first electrodes E1-1 to E1-5 and the sensing patterns SP2 may be formed from the first conductive patterns IS-CL1 illustrated in FIG. 6A, and the bridge patterns CP2 may be formed from the second conductive patterns IS-CL2.

One of the first signal lines SL1 and the second signal lines SL2 may receive a transmit signal for sensing an external input from an external circuit, and another of the first signal lines SL1 and the second signal lines SL2 may transmit, to the external circuit, a change in capacitance between the first electrodes E1-1 to E1-5 and the second electrodes E2-1 to E2-4 in the form of a receive signal.

Some of the second conductive patterns IS-CL2 described above may correspond to the first signal lines SL1 and the second signal lines SL2. The first signal lines SL1 and the second signal lines SL2 may have a multi-layer structure, and may include a first layer line formed from the first conductive patterns IS-CL1 and a second layer line formed from the second conductive patterns IS-CL2. The first layer line and the second layer line may be connected through a contact hole formed through the second sensing insulating layer IS-IL2.

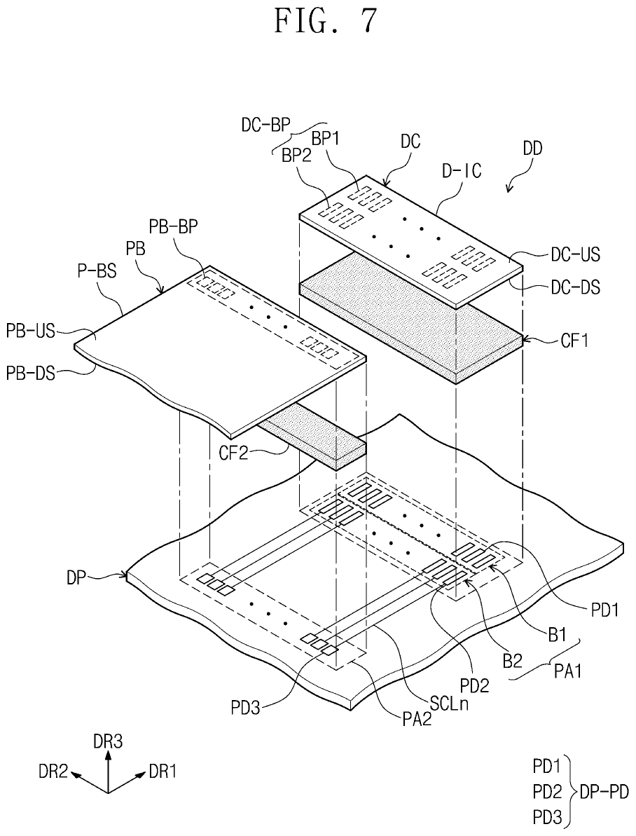

FIG. 7 is an enlarged exploded schematic perspective view of pad regions PA1 and PA2 of the display device DD according to an embodiment of the disclosure. For example, FIG. 7 illustrates that the driving chip DC and the circuit board PB are exploded from the display panel DP. Since the first pads PD1, the second pads PD2, the connection signal lines SCLn, and the third pads PD3 of FIG. 7 may be the same as the first pads PD1, the second pads PD2, the connection signal lines SCLn, and the third pads PD3 of FIG. 4, the description thereof will be omitted or simplified.

Referring to FIGS. 4 and 7, the driving chip DC may be bonded to the first pad region PA1 through a first adhesive layer CF1. The circuit board PB may be bonded to the second pad region PA2 through a second adhesive layer CF2. The first and second adhesive layers CF1 and CF2 may include a synthetic resin having adhesiveness. According to an embodiment, the first and second adhesive layers CF1 and CF2 may not include conductive balls, and may include only a synthetic resin having adhesive properties.

The driving chip DC may include a driving integrated circuit D-IC and chip bump electrodes DC-BP mounted in the driving chip DC. The driving integrated circuit D-IC may include a top surface DC-US and a bottom surface DC-DS, and the bottom surface DC-DS may be a surface facing the first and second pads PD1 and PD2. The chip bump electrodes DC-BP may be disposed on the bottom surface DC-DS of the driving integrated circuit D-IC.

The chip bump electrodes DC-BP may include first bumps BP1 electrically connected to the first pads PD1, respectively, and second bumps BP2 electrically connected to the second pads PD2, respectively. The first bumps BP1 may be arranged in the second direction DR2, and the second bumps BP2 may be spaced apart from the first bumps BP1 in the first direction DR1 and may be arranged in the second direction DR2.

The driving chip DC may receive first signals from the outside through the second pads PD2 and the second bumps BP2. The driving chip DC may provide second signals generated based on the first signals to the first pads PD1 through the first bumps BP1. For example, the driving chip DC may include a data driving circuit. The first signal may be an image signal that is a digital signal applied from the outside, and the second signal may be a data signal that is an analog signal. The driving chip DC may generate an analog voltage corresponding to a grayscale value of an image signal. The data signal may be provided to the pixel PX through the data line DL illustrated in FIG. 4.

Although not illustrated, the first bumps BP1 and the second bumps BP2 may have a form protruding from the bottom surface DC-DS of the driving integrated circuit D-IC and exposed to the outside. In case that the first adhesive layer CF1 is cured, the first pads PD1 and the first bumps BP1 may be fixed while contacting each other, and the second pads PD2 and the second bumps BP2 may be fixed while contacting each other.

The circuit board PB may include a base layer P-BS and the substrate bump electrodes PB-BP mounted in the circuit board PB. The circuit board PB may include a top surface PB-US and a bottom surface PB-DS, and the bottom surface PB-DS may be a surface facing the third pads PD3. The substrate bump electrodes PB-BP may be disposed on the bottom surface PB-DS of the base layer P-BS. The substrate bump electrodes PB-BP may be electrically connected to the third pads PD3, respectively. The substrate bump electrodes PB-BP may be arranged in the second direction DR2. The circuit board PB may provide an image signal, a driving voltage, and other control signals to the driving chip DC.

Although not illustrated, the substrate bump electrodes PB-BP may have a form protruding from the bottom surface PB-DS of the base layer P-BS and exposed to the outside. In case that the second adhesive layer CF2 is cured, the third pads PD3 and the substrate bump electrodes PB-BP may be fixed while contacting each other.

The electronic component may include a substrate and a bump electrode disposed under the substrate. In case that the electronic component corresponds to the driving chip DC, the substrate may correspond to the driving integrated circuit D-IC of the driving chip DC, and the bump electrode may correspond to the chip bump electrode DC-BP. As another example, in case that the electronic component corresponds to the circuit board PB, the substrate may correspond to the base layer P-BS of the circuit board PB, and the bump electrode may correspond to a substrate bump electrode PB-BP.

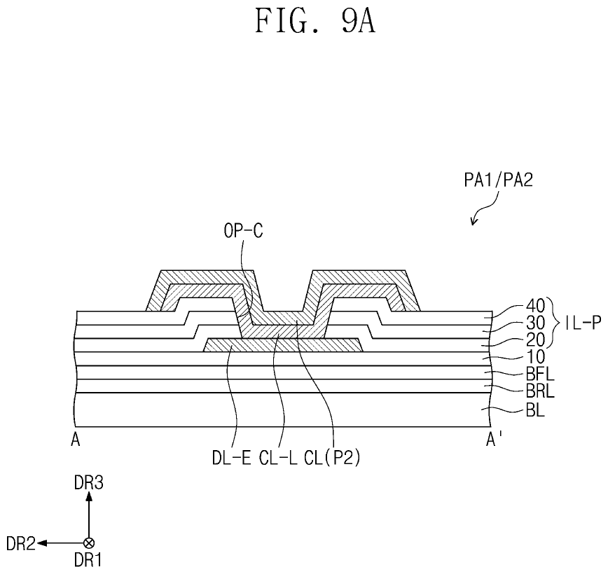

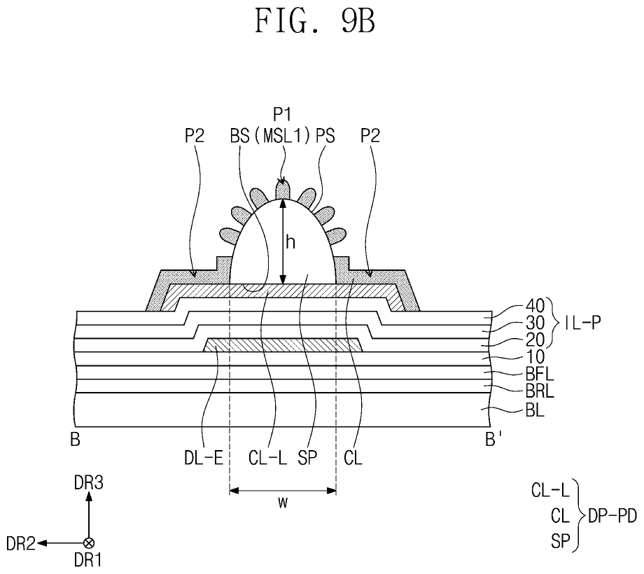

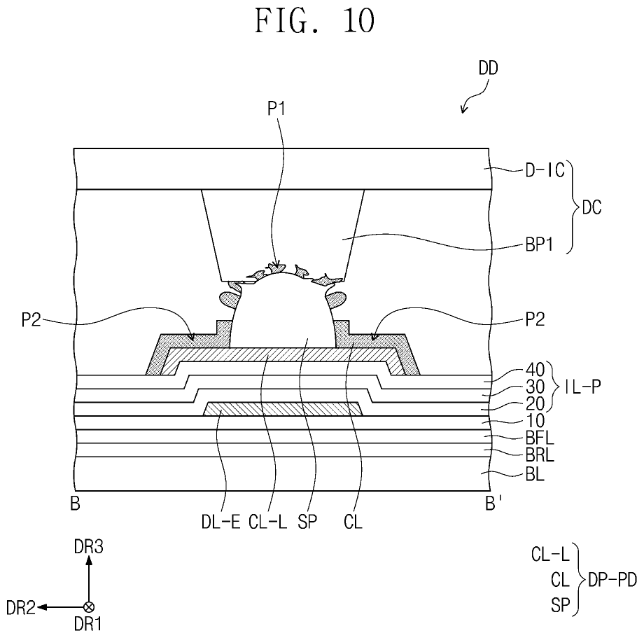

FIG. 8A is a schematic plan view of a pad region according to an embodiment of the disclosure. FIG. 8B is an enlarged schematic plan view illustrating a portion of a pad region according to an embodiment of the disclosure. FIGS. 9A and 9B are cross-sectional views corresponding to FIG. 8A. FIG. 10 is a schematic cross-sectional view illustrating a bonding structure of a display device according to an embodiment of the disclosure. FIG. 9A is a schematic cross-sectional view of the pad regions PA1 and PA2 taken along line A-A′ of FIG. 8A, and FIG. 9B is a schematic cross-sectional view of the pad regions PA1 and PA2 taken along line B-B′ of FIG. 8A.

FIG. 8A is a schematic plan view of the pad regions PA1 and PA2 according to an embodiment of the disclosure. FIG. 8B is a plan view illustrating the pad regions PA1 and PA2, in which region AA′ is expanded, according to an embodiment of the disclosure. FIGS. 9A and 9B are cross-sectional views corresponding to FIG. 8A. FIG. 10 is a cross-sectional view illustrating a bonding structure of the display device DD according to an embodiment of the disclosure. FIG. 9A is a cross-sectional view of the pad regions PA1 and PA2 taken along line A-A′ of FIG. 8A, and FIG. 9B is a cross-sectional view of the pad regions PA1 and PA2 taken along line B-B′ of FIG. 8A.

The signal pad (or a signal structure) DP-PD illustrated in FIGS. 8A to 10 may be any of the first to third pads PD1 to PD3 described with reference to FIGS. 4 and 7. FIG. 8A illustrates the data line DL including a distal end part DL-E and a line part DL-S, which have different widths, as an example of a signal line, but the disclosure is not limited thereto. The signal line may be a signal line other than the data line DL, and may have a uniform width without distinction between the distal end part DL-E and the line part DL-S.

Hereinafter, the pad regions PA1 and PA2 will be described while focusing on the first pad region PA1 in which the data line DL is disposed. The description of the second pad region PA2 will be understood by making reference to the description regarding the first pad region PA1, except that a connection signal line S-CL (see FIG. 4) is disposed instead of the data line DL.

Referring to FIG. 8A, the signal pad DP-PD may include a lower conductive pattern CL-L, a conductive pattern CL, and at least one insulating pattern SP. The lower conductive pattern CL-L may be connected to the distal end part DL-E of the data line DL through at least one contact hole OP-C. FIG. 8A illustrates the signal pad DP-PD including two contact holes OP-C and two insulating patterns SP.

When viewed in a plan view, the distal end part DL-E may have a form extending in the first direction DR1. In other words, the length or width of the distal end part DL-E in the first direction DR1 may be greater than the length or width of the distal end part DL-E in the second direction DR2.

When viewed in a plan view, the contact holes OP-C may overlap the distal end part DL-E. When viewed in a plan view, a portion of the lower conductive pattern CL-L may overlap the contact holes OP-C.

According to an embodiment, the contact holes OP-C may be disposed to be spaced apart from each other in the first direction DR1. For example, the contact holes OP-C may be disposed at a side (or upper side) of the distal end part DL-E in the first direction DR1 and at an opposite side (or lower side) of the distal end part DL-E in the first direction DR1, respectively. The arrangement of the contact holes is not limited to one embodiment.

When viewed in a plan view, the insulating patterns SP may be disposed outside the contact holes OP-C. According to an embodiment, the insulating patterns SP may be arranged in the first direction DR1. The insulating patterns SP may be disposed to be spaced apart from each other in the first direction DR1. According to an embodiment, the insulating patterns SP may be between the contact hole OP-C disposed at a side of the distal end part DL-E and the contact hole OP-C disposed at the opposite side of the distal end part DL-E. The arrangement of the insulating patterns SP is not limited to an embodiment.

Although FIG. 8A illustrates the insulating patterns SP having a rectangle, when viewed in a plan view, the disclosure is not limited thereto. The shape of the insulating patterns SP when viewed in a plan view may be changed to a polygonal shape, a circular shape, an ellipse, instead of the rectangular shape. In addition, the shapes of the insulating patterns SP when viewed in a plan view are not limited to the same.

According to an embodiment, the conductive pattern CL may include at least one first part P1 and a second part P2 adjacent to the first part P1. According to an embodiment, the second part P2 may surround the first part P1 when viewed in a plan view. According to an embodiment, the first part P1 may overlap the relevant insulating pattern SP. The number of first parts P1 may be provided corresponding to the number of insulating patterns SP. FIG. 8A illustrates that the conductive pattern CL includes two first parts P1 overlapping two insulating patterns SP, respectively.

FIG. 8B illustrates an enlarged portion of the conductive pattern CL to describe a shape of the first part P1 of the conductive pattern CL, and the insulating pattern SP is illustrated together for convenience of description. FIG. 8B illustrates a contact portion between the first part P1 of the conductive pattern CL and the insulating pattern SP.

Referring to FIG. 8B, the first part P1 of the conductive pattern CL may be provided in a mesh shape. The first part P1 of the conductive pattern CL may be referred to as a mesh part, and the second part P2 of the conductive pattern CL may be referred to as a peripheral part.

The conductive pattern CL may include, in the first part P1, first mesh lines MSL1 extending in the first direction DR1 and arranged in the second direction DR2, and second mesh lines MSL2 extending in the second direction DR2, crossing the first mesh lines MSL1, and arranged in the first direction DR1.

FIG. 8B illustrates that the first mesh lines MSL1 and the second mesh lines MSL2 all have the same width, but the disclosure is not limited thereto. The first mesh lines MSL1 and/or the second mesh lines MSL2 may have a width varying depending on the arrangement direction.

FIG. 8B illustrates that the first mesh lines MSL1 and the second mesh lines MSL2 are arranged to have a specific distance from each other, but the disclosure is not limited thereto. The first mesh lines MSL1 and/or the second mesh lines MSL2 may be arranged to have a distance varying depending on the arrangement directions.

According to an embodiment, as the first part P1 of the conductive pattern CL has a mesh shape, a portion of the insulating pattern SP may be exposed from the conductive pattern CL.

Referring to FIGS. 9A and 9B, the distal end part DL-E may be disposed on the first insulating layer 10. The distal end part DL-E may be disposed on the same layer as the gates G1 and G2 illustrated in FIG. 5. The distal end part DL-E may be formed through the same process as the gates G1 and G2.

However, the position of the distal end part DL-E is not limited thereto. The distal end part DL-E may be disposed on the same layer as the upper electrode UE illustrated in FIG. 5 or the connection electrode CNE-G3 of the third conductive layer CL30 illustrated in FIG. 5, may include a material the same as a material of the upper electrode UE or the connection electrode CNE-G3, and may have a structure the same as that of the upper electrode UE or the connection electrode CNE-G3. Some of the signal lines may be formed through the same process as the gates G1 and G2, and other signal lines may be formed through the same process as the upper electrode UE or the connection electrode CNE-G3 of the third conductive layer CL30.

The data line DL may be disposed on a layer to have an integral shape, but the disclosure is not limited thereto. A data line DL may include multiple portions disposed on different layers. For example, the line part DL-S may include two or more portions.

The lower conductive pattern CL-L may be disposed on the fourth insulating layer 40. The lower conductive pattern CL-L may be connected to the distal end part DL-E through the contact hole OP-C formed through the second insulating layer 20, the third insulating layer 30, and the fourth insulating layer 40. In other words, the lower conductive pattern CL-L may contact the distal end part DL-E through the contact hole OP-C. The second to fourth insulating layers 20, 30, and 40 may be formed through the same process as the second to fourth insulating layers 20, 30, and 40 of the display region DP-DA (see FIG. 4) illustrated in FIG. 5. In the specification, an insulating layer disposed between the distal end part DL-E and the lower conductive pattern CL-L may be defined as a pad insulating layer IL-P. According to an embodiment, the second to fourth insulating layers 20, 30, and 40 may be defined as the pad insulating layer IL-P. The stack structure of the pad insulating layer IL-P may be changed according to the stack structure of the circuit element layer DP-CL. According to an embodiment, the contact hole OP-C may be defined in a larger number of insulating layers than the second to fourth insulating layers 20, 30, and 40.

The lower conductive pattern CL-L and the distal end part DL-E may be separated from each other by the pad insulating layer IL-P (for example, the second to fourth insulating layers 20, 30, and 40). The pad insulating layer IL-P may be between the lower conductive pattern CL-L and the distal end part DL-E.

The conductive pattern CL may be disposed on the lower conductive pattern CL-L. A region, which is in a non-overlap region with the insulating pattern SP, of the conductive pattern CL may contact the lower conductive pattern CL-L.

According to an embodiment, the lower conductive pattern CL-L may be formed through the same process as some (for example, the third to fifth conductive layers CL30 to CL50 of FIG. 5) of the conductive layers including connection electrodes. The conductive pattern CL may be formed through the same process as other layers of the conductive layer, which are disposed on the some (for example, the third to fifth conductive layers CL30 to CL50 of FIG. 5) of the conductive layers including the connection electrodes. Accordingly, the lower conductive pattern CL-L may include a material the same as a material of the some of the conductive layers including the connection electrodes, and the conductive pattern CL may include a material the same as a material of other layers of the conductive layers including the connection electrodes.

According to an embodiment, the lower conductive pattern CL-L may be formed through the same process as the fourth conductive layer CL40 of FIG. 5, and the conductive pattern CL may be formed through the same process as the fifth conductive layer CL50 of FIG. 5. However, the disclosure is not limited thereto. The distal end part DL-E, the lower conductive pattern CL-L, and the conductive pattern CL may be variously provided in the combination form of different layers among the first to fifth conductive layers CL10 to CL50 of FIG. 5. In addition, the combination form of conductive layers formed through the same process as the distal end part DL-E, the lower conductive pattern CL-L, and the conductive pattern CL may be selected in various manners depending on the stack structure of the circuit element layer DP-CL.

The lower conductive pattern CL-L and the conductive pattern CL may include a conductive material. According to an embodiment, the lower conductive pattern CL-L and the conductive pattern CL may have stack structures of Ti/Al/Ti, Ti/CU, Ti/ITO, Ti/Al, or Ti/Al/TiN. However, the materials and stack structures included in the lower conductive pattern CL-L and the conductive pattern CL are not limited to any one embodiment.

Although the drawing illustrates that an edge of the conductive pattern CL is disposed outside the edge of the lower conductive pattern CL-L and covers the edge of the lower conductive pattern CL-L, the disclosure is not limited thereto. The edge of the conductive pattern CL may be substantially aligned with the edge of the lower conductive pattern CL-L.

The insulating pattern SP may be between the lower conductive pattern CL-L and the conductive pattern CL, when viewed in a cross-sectional view. The insulating pattern SP is disposed on the lower conductive pattern CL-L, and may be partially covered by the conductive pattern CL. The insulating pattern SP may be directly disposed on the lower conductive pattern CL-L.

The insulating pattern SP may have a semicircular shape when viewed in a cross-sectional view. The insulating pattern SP may include a bottom surface BS and a protruding surface PS, and the protruding surface PS of the insulating pattern SP may have a semicircular shape when viewed in a cross-sectional view. According to an embodiment, the bottom surface BS of the insulating pattern SP may contact the lower conductive pattern CL-L. A portion of the conductive pattern CL may contact the protruding surface PS of the insulating pattern SP. The first part P1 of the conductive pattern CL may contact a part of the protruding surface PS of the insulating pattern SP, and the second part P2 of the conductive pattern CL may contact a part of the protruding surface PS of the insulating pattern SP and the top surface of the lower conductive pattern CL-L. A portion of the protruding surface PS of the insulating pattern SP may be exposed from the conductive pattern CL. According to an embodiment of the disclosure, the second part P2 of the conductive pattern CL may not contact the insulating pattern SP.

The insulating pattern SP may include polymer. The insulating pattern SP may include thermosetting polymer. However, the disclosure is not limited thereto, and the insulating pattern SP may include a thermoplastic polymer.

According to an embodiment, the insulating pattern SP may be formed through the same process as an organic layer disposed on the circuit element layer DP-CL. Accordingly, an additional process for forming the insulating pattern SP may not be required. For example, the insulating pattern SP may be formed through the same process as that of the fifth insulating layer 50 (see FIG. 5). However, the disclosure is not limited thereto, and the combination of connection electrodes formed through the same process as the lower conductive pattern CL-L and the conductive pattern CL may be variously selected according to a stack structure of the circuit element layer DP-CL (see FIG. 5). Accordingly, an insulating layer formed through the same process as the insulating pattern SP may be variously selected.

FIG. 9B illustrates the maximum width “w” (e.g., the width of the bottom surface BS of the insulating pattern SP) and the height “h” of the insulating pattern SP, and the maximum width “w” of the insulating pattern SP and the height “h” of the insulating pattern SP may be variously set. The ratio between the maximum width “w” and the height “h” of the insulating pattern SP may be variously set.

A portion, which covers the insulating pattern SP, of the conductive pattern CL may protrude from the lower conductive pattern CL-L in case compared to another portion of the conductive pattern CL. FIG. 9B illustrates a cross-sectional view of a portion, which does not cross the second mesh lines MSL2 (see FIG. 8B), of the first mesh lines MSL1. As illustrated in FIG. 9B, each of the first mesh lines MSL1 may protrude in a direction away from the protruding surface PS of the insulating pattern SP when viewed in a cross-sectional view. Each of the first mesh lines MSL1 may be provided in the form of protrusions protruding from the insulating pattern SP, when viewed in a cross-sectional view.

According to an embodiment, the end portion of each of the first mesh lines MSL1 may have a round shape when viewed in a cross-sectional view. However, the disclosure is not limited thereto, and the end portions of each of the first mesh lines MSL1 may have an angled shape, when viewed in a cross-sectional view.

FIG. 9B illustrates that the first mesh lines MSL1 provide protrusions having substantially the same protruding length, but the disclosure is not limited thereto. The protrusions provided by the first mesh lines MSL1 may have different protrusion lengths from each other, for example, the protrusions may have a protrusion length increasing outward from the central part of the insulating pattern SP.

Even in a cross-section of a portion, which does not cross the first mesh lines MSL1, of the second mesh lines MSL2, each of the second mesh lines MSL2 protrudes in a direction away from the protruding surface PS of the insulating pattern SP, when viewed in a cross-sectional view, and may be provided in the form of protrusions protruding from the insulating pattern SP on the cross-section. In other words, according to an embodiment, the first mesh lines MSL1 may provide the form of the plurality of protrusions, when viewed in the cross-sectional view in the first direction DR1, and the second mesh lines MSL2 may provide the form of the plurality of protrusions when viewed in the cross-sectional view in the second direction DR2.

FIG. 10 illustrates the driving chip DC as an electronic component. FIG. 10 illustrates a state in which a first bump BP1 of the chip bump electrodes DC-BP (see FIG. 7) of the driving chip DC makes contact with the conductive pattern CL.

The first bump BP1 of the driving chip DC may pass through the first adhesive layer CF1 to contact at least a portion of the first part P1 of the conductive pattern CL through bonding pressure. The first adhesive layer CF1 before curing may have a lower viscosity than that of the anisotropic conductive film. The anisotropic conductive film has a larger viscosity to induce the alignment of the conductive balls.

Since the first part P1 of the conductive pattern CL is disposed on the insulating pattern SP and protrudes toward the first bump BP1, the first part P1 and the first bump BP1 may be in closer contact with each other, and the contact resistance between the first part P1 and the first bump BP1 may be reduced. As the conductive balls are omitted, short circuit defects resulting from the conductive balls may be reduced, even if the signal pads DP-PD are densely provided. Since accessibility between the signal pad DP-PD and the first bump BP1 is improved, the bonding pressure may be reduced. As the bonding pressure is reduced, the physical damage to the display panel DP or the electronic component, which is caused in the bonding process, may be reduced.

According to an embodiment, as a portion, which includes the mesh pattern, of the conductive pattern CL in the signal pad DP-PD is disposed on the insulating pattern SP, the mesh pattern of the conductive pattern CL may have the form protruding from the insulating pattern SP. The insulating pattern SP may provide higher resilience against the bonding pressure. Accordingly, the mesh pattern of the conductive pattern CL and the bump electrode (for example, the first bump BP1) may make close contact with each other.

In addition, as the mesh pattern of the conductive pattern CL is disposed on the insulating pattern SP, the mesh pattern of the conductive pattern CL may be provided in the form of a protrusion protruding from the insulating pattern SP. In other words, each of the mesh lines MSL1 and MSL2 (see FIG. 8B) constituting the mesh pattern may correspond to a protrusion for the insulating pattern SP. Accordingly, pressure may be provided to each of the protrusions corresponding to the mesh lines MSL1 and MSL2 (see FIG. 8B) during the bonding process. Accordingly, the degree of pressing in the conductive pattern CL covering the insulating pattern SP in the mesh pattern may be increased in case compared to the case of covering the entire portion of the insulating pattern SP. Accordingly, the mesh pattern of the conductive pattern CL may have a relatively large degree of tension. Even after the bonding process is completed, the mesh pattern of the conductive pattern CL maintains the close contact with the bump electrode to maintain stable electrical connection. More specifically, even after the bonding pressure is removed, a gap between the mesh pattern of the conductive pattern CL and the bump electrode may be prevented from being formed, or the formation of the gap may be reduced. Accordingly, bonding resistance between the conductive pattern CL and the bump electrode may be reduced, and the display device DD (see FIG. 1) improved in bonding reliability may be provided.

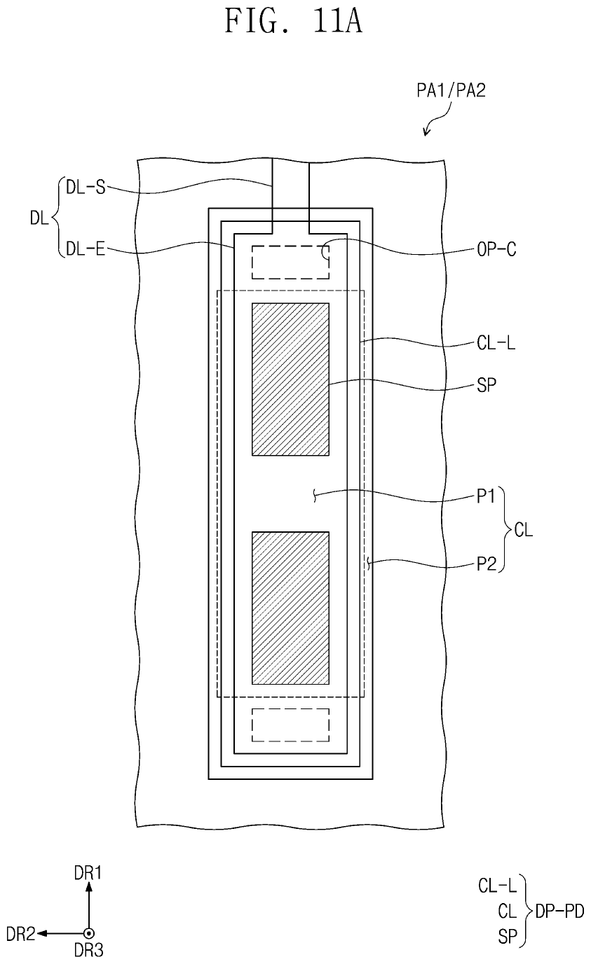

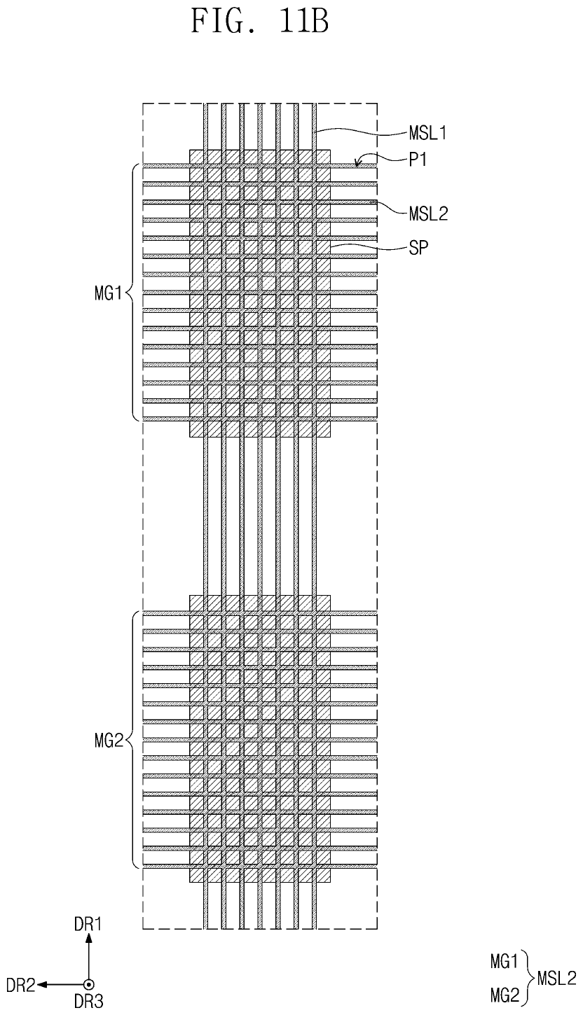

FIG. 11A is a schematic plan view of the pad regions PA1 and PA2 according to an embodiment of the disclosure. FIG. 11B is an enlarged schematic plan view illustrating portions of the pad regions PA1 and PA2 according to an embodiment of the disclosure. In the following description, the same/similar reference numerals are assigned to the same/similar components as/to components described in FIGS. 1 to 10, redundant descriptions are omitted, and differences are described.

Referring to FIG. 11A, according to an embodiment, the signal pad DP-PD may include the lower conductive pattern CL-L, the conductive pattern CL, and the at least one insulating pattern SP.

The conductive pattern CL may include the at least one first part P1 and the second part P2 adjacent to the first part P1. The second part P2 may surround the first part P1, when viewed in a plan view. According to an embodiment, multiple insulating patterns SP may overlap a first part P1. In other words, the first part P1 may be disposed on multiple insulating patterns SP. FIG. 11A illustrates that the conductive pattern CL includes a first part P1, the signal pad DP-PD includes two insulating patterns SP arranged in the first direction DR1, and a first part P1 is commonly disposed on the two insulating patterns SP.

FIG. 11B illustrates an enlarged view of the first part P1 of the conductive pattern CL to describe a planar shape of the first part P1 of the conductive pattern CL, and illustrates the insulating patterns SP together for convenience of description.

As illustrated in FIG. 11B, the first part P1 of the conductive pattern CL may be provided in the form of a mesh pattern. The mesh pattern of the first part P1 may include the first mesh lines MSL1 extending in the first direction DR1 and arranged in the second direction DR2, and the second mesh lines MSL2 extending in the second direction DR2, crossing the first mesh lines MSL1, and arranged in the first direction DR1.

According to an embodiment, the first mesh lines MSL1 may cross each of the insulating patterns SP arranged in the first direction DR1, when viewed in a plan view. The second mesh lines MSL2 may include first group lines MG1 and second group lines MG2. The first group lines MG1 may cross the insulating pattern SP disposed at an upper side of the two insulating patterns SP, when viewed in a plan view. The second group lines MG2 may cross the insulating pattern SP disposed at a lower side of the two insulating patterns SP, when viewed in a plan view.

The arrangement of the first and second mesh lines MSL1 and MSL2 may vary depending on the number and arrangement of the insulating patterns SP. For example, in case that the insulating patterns SP are arranged in the second direction DR2, the first mesh lines MSL1 may include multiple group lines. In case that the insulating patterns SP are arranged along in both the first direction DR1 and the second direction DR2, the first mesh lines MSL1 and the second mesh lines MSL2 may include multiple group lines.

The disclosure is not limited to the configuration illustrated in FIG. 11B. For example, the first mesh lines MSL1 and/or the second mesh lines MSL2 may be disposed even at a portion where the insulating patterns SP may not be disposed, such that some of the first mesh lines MSL1 and/or the second mesh lines MSL2 may not cross the insulating patterns SP.

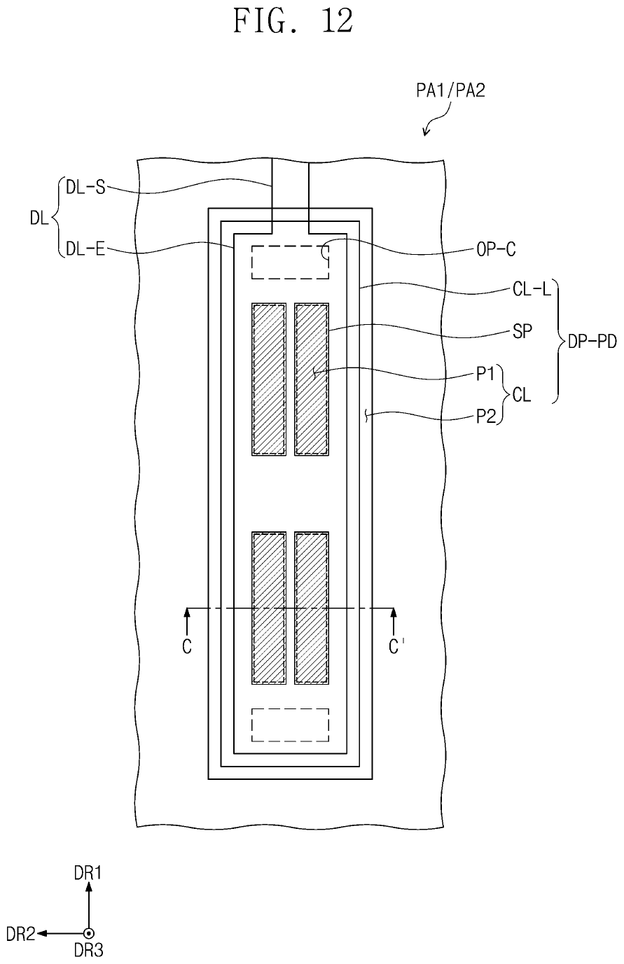

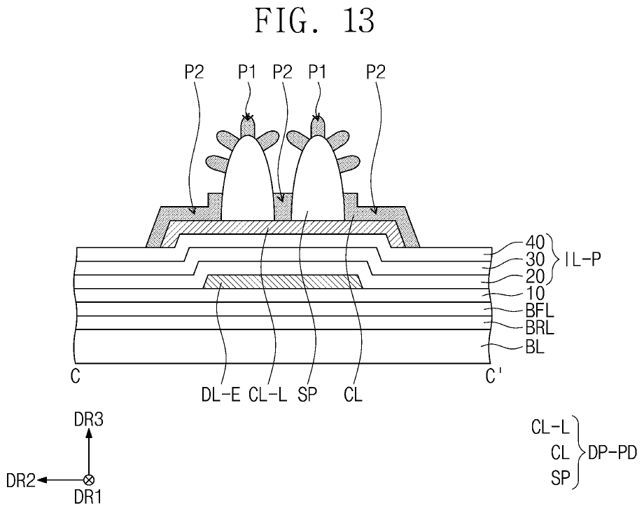

FIG. 12 is a schematic plan view of the pad regions PA1 and PA2 according to an embodiment of the disclosure. FIG. 13 is a schematic cross-sectional view corresponding to FIG. 12. FIG. 13 is a cross-sectional view of the pad regions PA1 and PA2 taken along line C-C′ of FIG. 12. In the following description, the same/similar reference numerals are assigned to the same/similar components as/to components described in FIGS. 1 to 10, redundant descriptions are omitted, and differences are described.

Referring to FIG. 12, the signal pad DP-PD according to an embodiment may include the lower conductive pattern CL-L, the conductive pattern CL, and the at least one insulating pattern SP.

According to an embodiment, the insulating patterns SP may be arranged in both the first direction DR1 and the second direction DR2. In other words, the insulating patterns SP may be arranged in the form of m rows and n columns, (“m” and “n” are natural numbers of at least ‘2’). FIG. 12 illustrates that the signal pad DP-PD includes four insulating patterns SP, and the four insulating patterns SP are arranged in a form of two rows and two columns. The number of the insulating patterns SP is not limited thereto.

The conductive pattern CL may include first parts P1 and the second part P2 surrounding the first parts P1 when viewed in a plan view. Each of the first parts P1 may overlap the relevant insulating pattern SP. Each of the first parts P1 may overlap the relevant insulating pattern SP. FIG. 12 illustrates that the conductive pattern CL includes four first parts P1 respectively disposed on four insulating patterns SP. The number of the first parts P1 may vary depending on the number of the insulating patterns SP.

Each of the first parts P1 of the conductive pattern CL may be provided in a mesh pattern, as described above with reference to FIG. 8B. The mesh pattern of each of the first parts P1 may include the first mesh lines MSL1 (see FIG. 8B) extending in the first direction DR1 and arranged in the second direction DR2, and the second mesh lines MSL2 (see FIG. 8B), extending in the second direction DR2, crossing the first mesh lines MSL1 (see FIG. 8B), and arranged along the first direction DR1.

The conductive pattern CL may be provided such that a first part P1 is disposed across multiple insulating patterns SP when viewed in a plan view, similar to which described above in FIG. 11B, and the first mesh lines MSL1 (see FIG. 11B) and/or the second mesh lines MSL2 (see FIG. 11B) may include multiple group lines. In this case, the number of insulating patterns SP crossing the first part P1 when viewed in a plan view is not limited to any one embodiment.

Referring to FIGS. 12 and 13, multiple insulating patterns SP arranged in the second direction DR2 may be disposed on the lower conductive pattern CL-L, when viewed on a cross-section of the signal pad DP-PD in the first direction DR1. In the following description, the same/similar reference numerals are assigned to the same/similar components as/to components described in FIGS. 1 to 11B, redundant descriptions are omitted, and differences are described.

According to an embodiment, the mesh pattern of the conductive pattern CL may be absent in portions, which are adjacent to each other, of the insulating patterns SP facing each other in the second direction DR2. In this case, when viewed in a cross-sectional view in the first direction DR1, the conductive pattern CL may have an asymmetric shape about the central line of an insulating pattern SP extending in the first direction DR1. However, FIG. 13 is illustrative and is not limited thereto. For example, if the insulating patterns SP facing each other in the second direction DR2 are spaced apart from each other by a sufficient distance, the conductive pattern CL may be provided to have a symmetric shape about the central line of an insulating pattern SP, which extends in the first direction, in the second direction DR2.

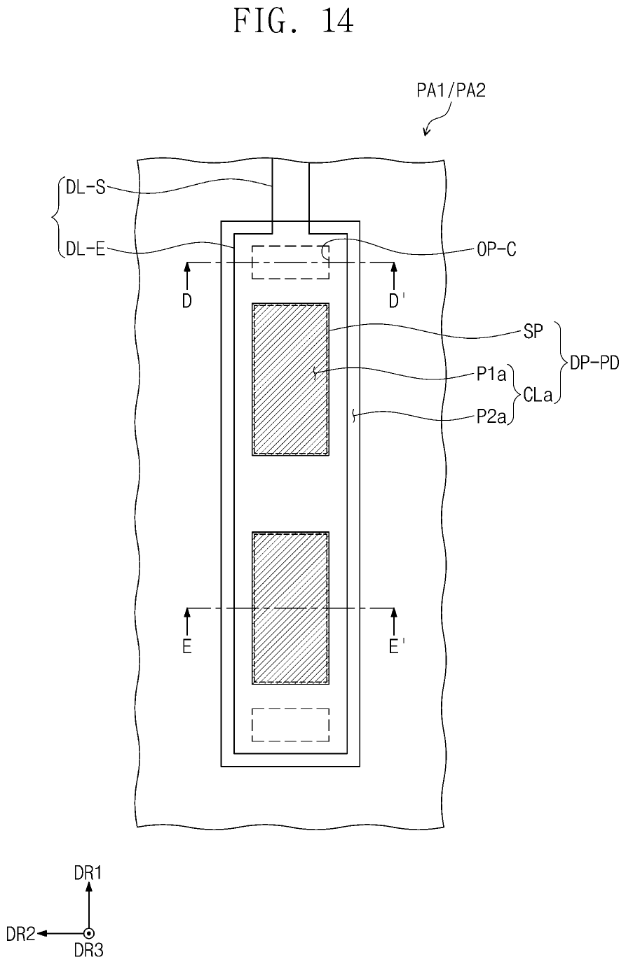

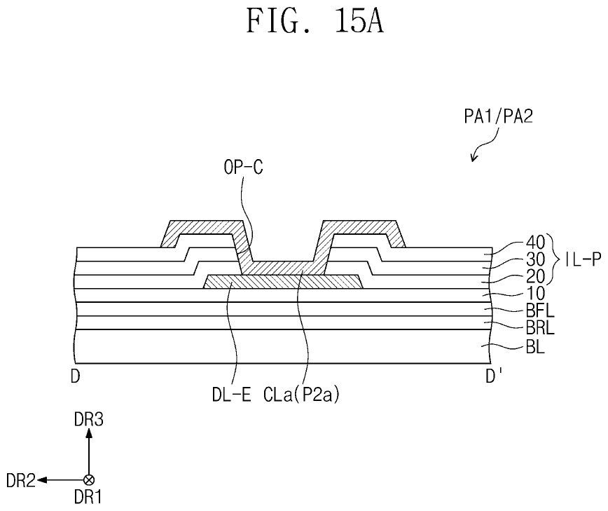

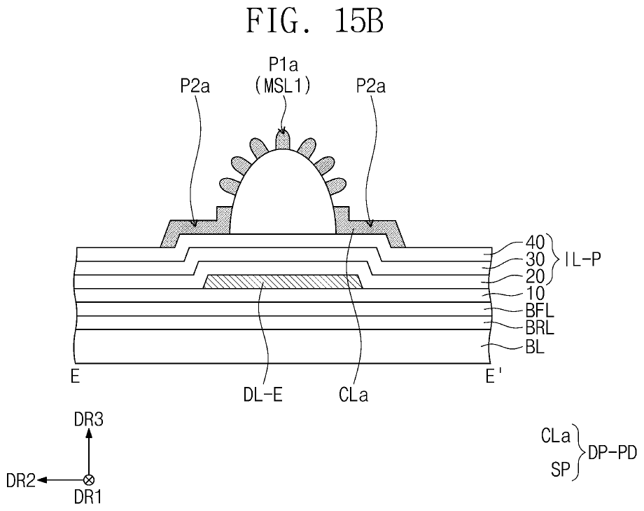

FIG. 14 is a schematic plan view of the pad regions PA1 and PA2 according to an embodiment of the disclosure. FIGS. 15A and 15B are cross-sectional views corresponding to FIG. 14. FIG. 15A is a schematic cross-sectional view of the pad regions PA1 and PA2 taken along line D-D′ of FIG. 14, and FIG. 15B is a schematic cross-sectional view of the pad regions PA1 and PA2 taken along line E-E′ of FIG. 14. In the following description, the same/similar reference numerals are assigned to the same/similar components as/to components described in FIGS. 1 to 13, redundant descriptions are omitted, and differences are described.

Referring to FIGS. 14 to 15B, the signal pad DP-PD according to an embodiment may include a conductive pattern CLa and at least one insulating pattern SP. In case compared to the above-described embodiments, the signal pad DP-PD may not include the lower conductive pattern. The conductive pattern CLa may be connected to the distal end part DL-E of the data line DL through at least one contact hole OP-C.

According to an embodiment, the conductive pattern CLa may cover a portion of the insulating pattern SP. The conductive pattern CLa may include at least one first part P1a and a second part P2a adjacent to the first part P1a. At least one first part P1a may be spaced apart from the contact hole OP-C. The second part P2a may surround the first part P1a when viewed in a plan view.

FIG. 14 illustrates that the signal pad DP-PD includes two insulating patterns SP arranged in the first direction DR1, and the conductive pattern CLa includes two first parts P1a overlapping the two insulating patterns SP, respectively.

Each of the first parts P1a of the conductive pattern CLa may be provided in a mesh pattern similar to a mesh pattern illustrated in FIG. 8B. The mesh pattern of each of the first parts P1a may include the first mesh lines MSL1 (see FIG. 8B) extending in the first direction DR1 and arranged in the second direction DR2, and the second mesh lines MSL2 (see FIG. 8B) extending in the second direction DR2, crossing the first mesh lines MSL1 (see FIG. 8B), and arranged in the first direction DR1.

According to an embodiment, the conductive pattern CLa may be formed through the same process as some of the conductive layers (for example, the third to fifth conductive layers CL30 to CL50 in FIG. 5) including connection electrodes. Accordingly, the conductive pattern CLa may include the same material as the some of the conductive layers including the connection electrodes.

According to an embodiment, the conductive pattern CLa may be formed through the same process as the fifth conductive layer CL50 in FIG. 5. However, the disclosure is not limited thereto. The distal end part DL-E and the conductive pattern CLa may be variously provided in the form of the combination of different layers among the first to fifth conductive layers CL10 to CL50 in FIG. 5. In addition, the combination of conductive layers formed through the same process as the distal end part DL-E and the conductive pattern CLa may be selected in various manners depending on the stack structure of the circuit element layer DP-CL (see FIG. 5).

The insulating pattern SP may be disposed between the pad insulating layer IL-P and the conductive pattern CLa when viewed in a cross-sectional view. The insulating pattern SP may be disposed on the pad insulating layer IL-P, and may be partially covered by the conductive pattern CLa.

According to an embodiment, a portion, which covers the insulating pattern SP, of the conductive pattern CLa may further protrude from the conductive pattern CLa, in case compared to a remaining portion of the conductive pattern CLa. FIG. 15B illustrates a cross-sectional view of the signal pad DP-PD viewed in the first direction DR1, and the first part P1a of the conductive pattern CLa illustrated in FIG. 15B may be the first mesh lines MSL1. Each of the first mesh lines MSL1 of the conductive pattern CLa may be provided in the form of protrusions protruding from the insulating pattern SP, when viewed in a cross-sectional view. On the cross section of the signal pad DP-PD viewed in the second direction DR2, the second mesh lines MSL2 of the conductive pattern CLa (see FIG. 8B) may be provided in the form of the plurality of protrusions protruding from the insulating pattern SP.

According to an embodiment, as the mesh pattern of the conductive pattern CLa is disposed on the insulating pattern SP in the signal pad DP-PD, the mesh pattern of the conductive pattern CLa may be provided in the form of a protrusion protruding from the insulating pattern SP. Accordingly, pressure may be applied to each of the protrusions corresponding to the mesh lines MSL1 and MSL2 (see FIG. 8B) during the bonding process. Accordingly, the degree of pressing in the conductive pattern CLa covering the insulating pattern SP in the mesh pattern may be increased in case compared to the case of covering the entire portion of the insulating pattern SP. Accordingly, the mesh pattern of the conductive pattern CLa may have a relatively large degree of tension. Even after the bonding process is completed, the mesh pattern of the conductive pattern CLa maintains the stable electrical connection with the bump electrode. Accordingly, the bonding resistance between the conductive pattern CLa and the bumper electrode, and the display device DD (see FIG. 1) improved in bonding reliability may be provided.

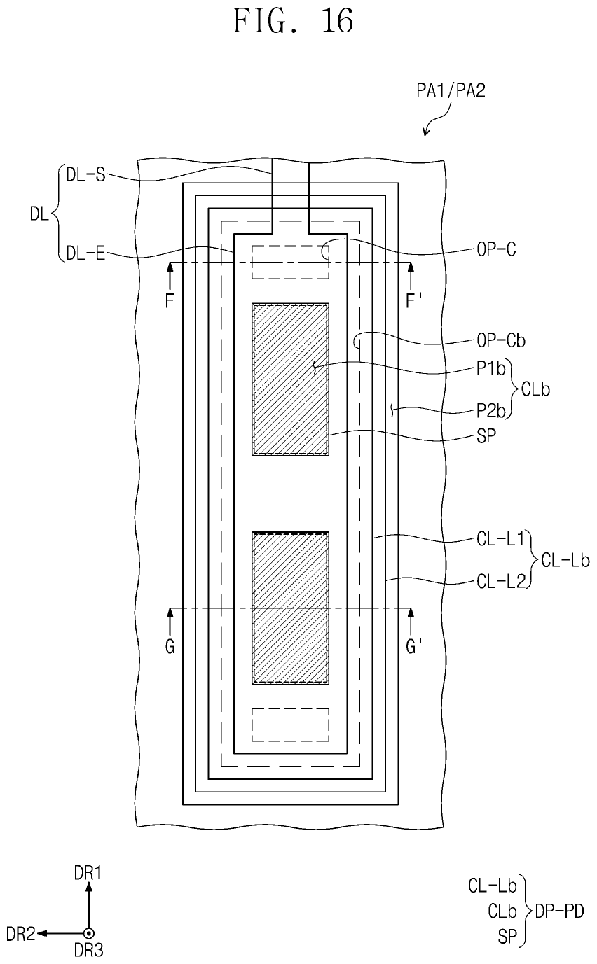

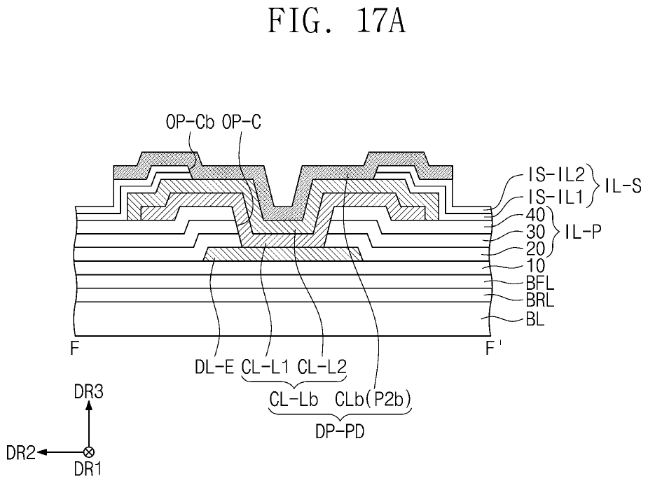

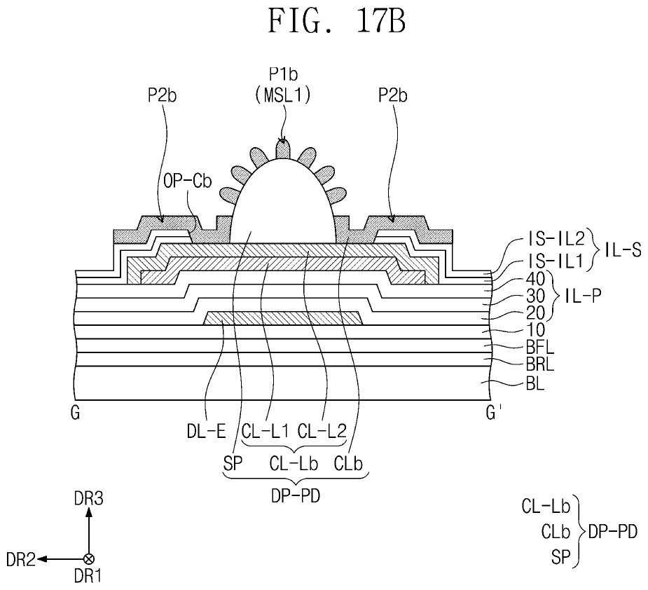

FIG. 16 is a schematic plan view of the pad regions PA1 and PA2 according to an embodiment of the disclosure. FIGS. 17A and 17B are cross-sectional views corresponding to FIG. 16. FIG. 17A is a schematic cross-sectional view of the pad regions PA1 and PA2 taken along line F-F′ of FIG. 16, and FIG. 17B is a schematic cross-sectional view of the pad regions PA1 and PA2 taken along line G-G′ of FIG. 16. In the following description, the same/similar reference numerals are assigned to the same/similar components as/to components described in FIGS. 1 to 13, redundant descriptions are omitted, and differences are described.

Referring to FIG. 16, according to an embodiment, the signal pad DP-PD may include a lower conductive pattern CL-Lb, a conductive pattern CLb, and at least one insulating pattern SP. The lower conductive pattern CL-Lb may be connected to the distal end part DL-E of the data line DL through at least one contact hole OP-C. The conductive pattern CLb may contact the lower conductive pattern CL-Lb through at least one upper contact hole OP-Cb. The signal pad DP-PD including two contact holes OP-C and an upper contact hole OP-Cb is illustrated in FIG. 16.

The upper contact hole OP-Cb may overlap at least a portion of the distal end part DL-E. Although FIG. 16 illustrates that the upper contact hole OP-Cb overlaps the entire portion of the distal end part DL-E, the disclosure is not limited thereto. For example, the upper contact hole OP-Cb may be defined to overlap a portion of the distal end part DL-E.

According to an embodiment, the contact holes OP-C may be disposed in the upper contact hole OP-Cb, when viewed in a plan view. However, the disclosure is not limited thereto, and the contact holes OP-C and the upper contact holes OP-Cb may be disposed to be spaced apart from each other when viewed in a plan view.

The insulating patterns SP may be spaced apart from the contact holes OP-C and may be disposed in the upper contact hole OP-Cb, when viewed in a plan view.

FIG. 16 illustrates the conductive pattern CLb having an area larger than that of the lower conductive pattern CL-Lb when viewed in a plan view, but the disclosure is not limited thereto. The conductive pattern CLb and the lower conductive pattern CL-Lb may have the same area, and edges of the conductive pattern CLb and the lower conductive pattern CL-Lb may be aligned in line with each other.

According to an embodiment, the conductive pattern CLb may cover a portion of the insulating pattern SP. The conductive pattern CLb may include at least one first part P1b and a second part P2b surrounding the at least one first part P1b when viewed in a plan view. FIG. 16 illustrates that the conductive pattern CLb includes two first parts P1b overlapped the two insulating patterns SP, respectively.

Each of the first parts P1b of the conductive pattern CLb may be provided in a mesh pattern similar to that illustrated in FIG. 8B. The mesh pattern of each of the first parts P1b may include first mesh lines MSL1 (see FIG. 8B) extending in the first direction DR1, and arranged in the second direction DR2, and the second mesh lines MSL2 (see FIG. 8) extending in the second direction DR2, crossing the first mesh lines MSL1 (see FIG. 8B), and arranged in the first direction DR1.

Referring to FIGS. 17A and 17B, according to an embodiment, the lower conductive pattern CL-Lb may include a first layer CL-L1 and a second layer CL-L2. Since the insulating layer is not disposed between the first layer CL-L1 and the second layer CL-L2, the first layer CL-L1 and the second layer CL-L2 may be defined in the form of a single conductive pattern. The first layer CL-L1 and the second layer CL-L2 may not be connected to each other through a contact hole.

According to an embodiment, the first layer CL-L1 may be formed through the same process as some of the conductive layers (for example, the third to fifth conductive layers CL30 to CL50 of FIG. 5) including connection electrodes. The second layer CL-L2 may be formed through the same process as other layers of the conductive layers (for example, the third to fifth conductive layers CL30 to CL50 of FIG. 5) including connection electrodes, which may be disposed on the some of the conductive layers. Accordingly, the first layer CL-L1 may include the same material as the some of the conductive layers including the connection electrodes, and the second layer CL-L2 may include the same material as other layers of the conductive layers including the connection electrodes.

According to an embodiment, the first layer CL-L1 may be formed through the same process as the fourth conductive layer CL40 of FIG. 5, and the second layer CL-L2 may be formed through the same process as the fifth conductive layer CL50 of FIG. 5. However, the disclosure is not limited thereto. The distal end part DL-E, the first and second layers CL-L1 and CL-L2 may be variously provided in the form of the combination of different layers among the first to fifth conductive layers CL10 to CL50 of FIG. 5. In addition, the combination of conductive layers formed through the same process as the distal end part DL-E and the first and second layers CL-L1 and CL-L2 may be selected in various manners depending on the stack structure of the circuit element layer (see FIG. 5).

According to an embodiment, any of the first layer CL-L1 and the second layer CL-L2 may be omitted. According to another embodiment of the disclosure, the lower conductive pattern CL-Lb may be omitted.

Although FIGS. 17A and 17B illustrate that the edge of the second layer CL-L2 is disposed outside the edge of the first layer CL-L1 and covers the edge of the first layer CL-L1, the disclosure is not limited thereto. The edge of the second layer CL-L2 may be substantially aligned in line with the edge of the first layer CL-L1.

According to an embodiment, insulating layers between the lower conductive pattern CL-Lb and the conductive pattern CLb may be defined as an upper pad insulating layer IL-S. The upper contact hole OP-Cb may be defined in the upper pad insulating layer IL-S. According to an embodiment, the first sensing insulating layer IS-IL1 and the second sensing insulating layer IS-IL2 may be defined as the upper pad insulating layer IL-S. The first sensing insulating layer IS-IL1 and the second sensing insulating layer IS-IL2 may overlap the sensing region IS-DA and the non-sensing region IS-NDA illustrated in FIG. 6B. Accordingly, the first sensing insulating layer IS-IL1 and the second sensing insulating layer IS-IL2 may overlap the pad regions PA1 and PA2. According to an embodiment of the disclosure, any of the first sensing insulating layer IS-IL1 and the second sensing insulating layer IS-IL2 may be omitted.

According to an embodiment, the conductive pattern CLb may be formed through the same process as the second conductive pattern layer IS-CL2 of FIG. 6A and the sensing patterns SP2 of FIG. 6C.

The insulating pattern SP may be between the lower conductive pattern CL-Lb and the conductive pattern CLb, when viewed in a cross-sectional view. The insulating pattern SP is disposed on the lower conductive pattern CL-Lb, and may be partially covered by the conductive pattern CLb.

According to an embodiment, the insulating pattern SP may be formed through the same process as the organic layer disposed on the circuit element layer DP-CL (see FIG. 5) or the display element layer DP-OLED (see FIG. 5). Accordingly, an additional process for forming the insulating pattern SP may not be required. For example, the insulating pattern SP may be formed through at least one of the fifth insulating layer 50 (see FIG. 5), the sixth insulating layer 60 (see FIG. 5), and the pixel defining film PDL (see FIG. 5). However, the disclosure is not limited thereto, and a combination of conductive layers formed through the same process as the first and second layers CL-L1 and CL-L2 of the lower conductive pattern CL-Lb may be variously selected depending on a stack structure of the circuit element layer DP-CL (see FIG. 5). Accordingly, even an insulating layer formed through the same process as the insulating pattern SP may be variously selected.

The conductive pattern CLb and the lower conductive pattern CL-Lb may be distinguished by the upper pad insulating layer IL-S (for example, the first sensing insulating layer IS-IL1 and the second sensing insulating layer IS-IL2). The upper pad insulating layer IL-S may be between the conductive pattern CLb and the lower conductive pattern CL-Lb, and the insulating pattern SP.

A portion, which covers the insulating pattern SP, of the conductive pattern CLb may protrude from the lower conductive pattern CL-Lb, in case compared to another part of the conductive pattern CLb. FIG. 17B illustrates a cross-sectional view of the signal pad DP-PD viewed in the first direction DR1, and the first part P1b of the conductive pattern CLb illustrated in FIG. 17B may be the first mesh lines MSL1. Each of the first mesh lines MSL1 of the conductive pattern CLb may be provided in the form of protrusions protruding from the insulating pattern SP, when viewed in a cross-sectional view. On the cross section of the signal pad DP-PD viewed in the second direction DR2, each the second mesh lines MSL2 (see FIG. 8B) of the conductive pattern CLb may also be provided in the form of the plurality of protrusions protruding from the insulating pattern SP.

According to an embodiment, the mesh pattern of the conductive pattern CLb may be provided in a protrusion form protruding from the insulating pattern SP by disposing the mesh pattern of the conductive pattern CLb on the insulating pattern SP in the signal pad DP-PD. Accordingly, pressure may be applied to each of the protrusions corresponding to the mesh lines MSL1 and MSL2 (see FIG. 8B) during the bonding process. Accordingly, the degree of pressing in the conductive pattern CLb covering the insulating pattern SP in the mesh pattern may be increased in case compared to the case of covering the entire portion of the insulating pattern SP. Accordingly, the mesh pattern of the conductive pattern CLb may have a relatively large degree of tension. Even after the bonding process is completed, the mesh pattern of the conductive pattern CLb maintains the close contact with the bump electrode to maintain stable electrical connection. Accordingly, bonding resistance between the conductive pattern CLb and the bump electrode may be reduced, and the display device DD (see FIG. 1) improved in bonding reliability may be provided.

Hereinafter, a method for manufacturing a display device according to an embodiment will be described with reference to accompanying drawings. In the following description regarding the method for manufacturing the display device according to an embodiment, the duplication of the description regarding the display device according to an embodiment will be omitted to avoid redundancy.

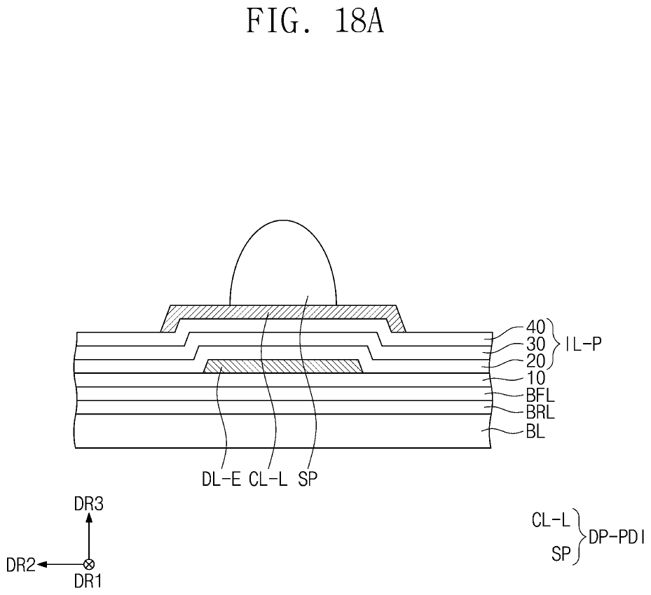

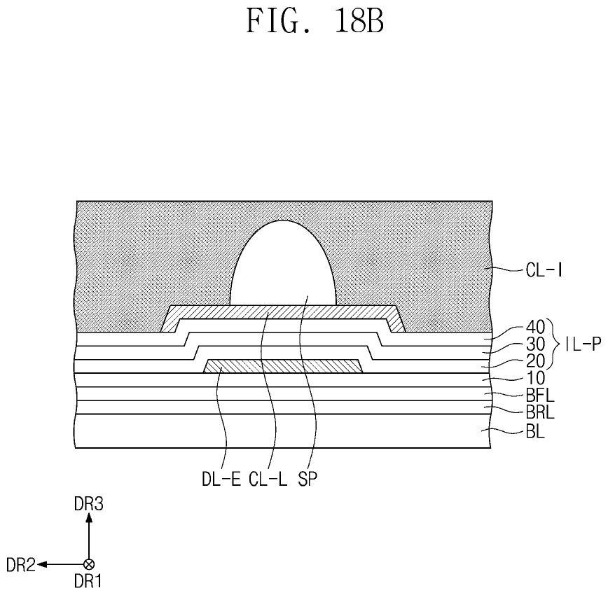

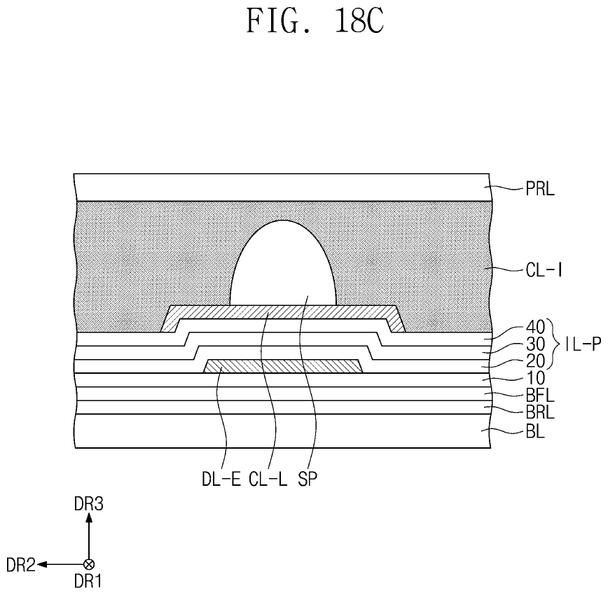

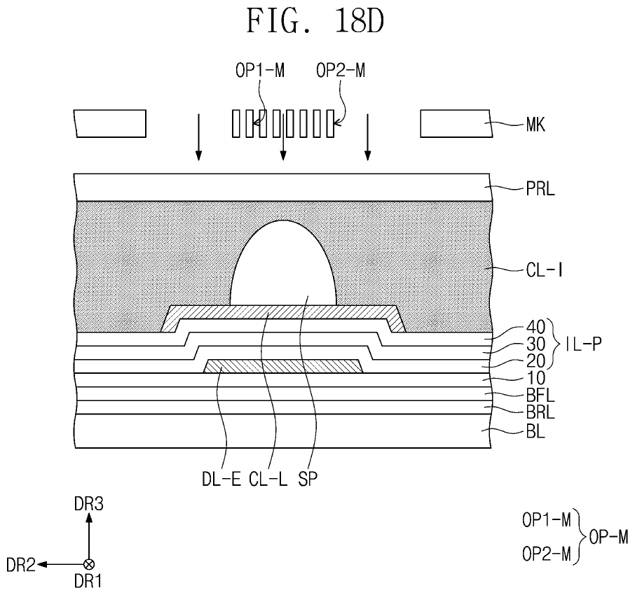

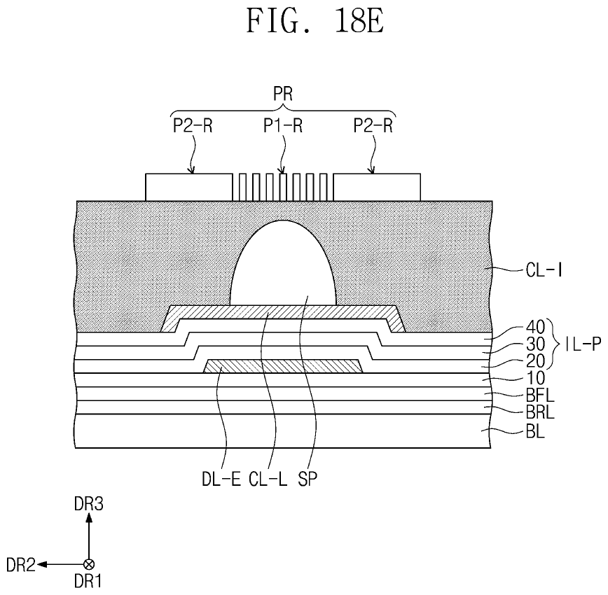

FIGS. 18A to 18E are schematic cross-sectional views illustrating some of the steps in the method for manufacturing a display device according to an embodiment of the disclosure.

The method for manufacturing a display device according to an embodiment of the disclosure includes the steps of providing a preliminary signal pad including an insulating pattern, depositing a preliminary conductive pattern on the preliminary signal pad, and patterning the preliminary conductive pattern to form a conductive pattern including a mesh pattern at least partially, and at least a portion of the mesh pattern is disposed on the insulating pattern.

Referring to FIG. 18A, the method for manufacturing the display device according to an embodiment of the disclosure may include providing a preliminary signal pattern DP-PDI.

The preliminary signal pattern DP-PDI may include the lower conductive pattern CL-L and the insulating pattern SP. The insulating pattern SP may be disposed on the lower conductive pattern CL-L to be provided. According to an embodiment, the preliminary signal pattern DP-PDI may include only the insulating pattern SP. In this case, the insulating pattern SP may be disposed and provided on the pad insulating layer IL-P. According to another embodiment, the upper pad insulating layer IL-S (see FIGS. 17A and 17B) covering a portion of the lower conductive pattern CL-L may be further provided.

Referring to FIG. 18B, the method for manufacturing a display device according to an embodiment of the disclosure may include forming a preliminary conductive pattern CL-I on the preliminary signal pattern DP-PDI.

The preliminary conductive pattern CL-I may be formed through a deposition process. The deposition process for the preliminary conductive pattern CL-I may be performed as a process of depositing a conductive material. For example, the deposition process for the preliminary conductive pattern CL-I may be performed through a chemical vapor deposition (CVD) scheme or a sputtering scheme.

According to an embodiment, the preliminary conductive pattern CL-I may be deposited to have a substantially flat top surface.

Referring to FIGS. 18C, 18D, and 9B, the method for manufacturing the display device according to an embodiment of the disclosure may include the step of patterning the preliminary conductive pattern CL-I to form the conductive pattern CL. According to an embodiment, the step of patterning the preliminary conductive pattern CL-I may include the steps of forming a photoresist pattern PR on the preliminary conductive pattern CL-I, etching a portion of the preliminary conductive pattern CL-I to form the conductive pattern CL, and removing the photoresist pattern PR to form the signal pad DP-PD.

According to an embodiment, the step of forming the photoresist pattern PR may include the steps of forming a photoresist layer PRL on the preliminary conductive pattern CL-I, exposing the photoresist layer PRL, and developing the photoresist layer PRL to form the photoresist pattern PR.

First, referring to FIG. 18C, the photoresist layer PRL may be formed by applying a photoresist material on the preliminary conductive pattern CL-I. Thereafter, a mask MK having opening parts OP-M defined to correspond to a region for forming the conductive pattern CL (see FIG. 9B) may be provided on the photoresist layer PRL. Thereafter, the exposure process of providing light on the mask MK may be performed. Through the exposure process, light may pass through the opening parts OP-M and be irradiated to portions of the photoresist layer PRL corresponding to the opening parts OP-M, respectively.

According to an embodiment, the opening parts OP-M defined in the mask MK may include a first opening part OP1-M and a second opening part OP2-M. Although not illustrated, when viewed in a plan view, the first opening part OP1-M may have a mesh pattern shape, and the second opening part OP2-M may be disposed outside the first opening part OP1-M.

Thereafter, referring to FIGS. 18D and 18E, portions of the photoresist layer PRL overlapping the opening parts OP-M remain by a developer provided through the developing process, and the remaining portions of the photoresist layer PRL, to which light is not irradiated, may be removed by overlapping the mask MK, to form the photoresist pattern PR.

According to an embodiment, the photoresist pattern PR may be formed from a first remaining part P1-R, which overlaps the first opening part OP1-M, of the photoresist layer PRL and a second remaining part P2-R, which overlaps the second opening part OP2-M, of the photoresist layer PRL. Although not illustrated, the first remaining part P1-R may have a mesh pattern shape corresponding to the first opening part OP1-M, and the second remaining part P2-R may be disposed outside the first remaining part P1-R.

Although the above description has been made regarding a positive photo process in which the photoresist pattern PR corresponding to the opening part OP-M of the mask MK is formed from the photoresist layer PRL, the disclosure is not limited thereto. For example, the photoresist pattern PR may be formed through a negative photo process in which a portion of the mask MK corresponding to the opening part OP-M is removed.

Thereafter, referring to FIGS. 18D and 9B, portions, which are exposed from the photoresist pattern PR, of the preliminary conductive pattern CL-I may be removed through an etching process to form the conductive pattern CL. The first part P1 of the conductive pattern CL may be formed from the preliminary conductive pattern CL-I through the first remaining part P1-R, and the second part P2 of the conductive pattern CL may be formed from the preliminary conductive pattern CL-I through the second remaining part P2-R. The photoresist pattern PR may remain on the conductive pattern CL. Thereafter, through the strip process, the photoresist pattern PR remaining on the conductive pattern CL may be removed to form the signal pad DP-PD. The signal pad DP-PD formed through the manufacturing steps of FIGS. 18A to 18E may have a shape similar to that of the signal pad DP-PD of FIG. 9B.

The thickness of the preliminary conductive pattern CL-I may be variously controlled. According to an embodiment of the disclosure, the top surface of a portion, which is in a non-overlap state with the insulating pattern SP, of the preliminary conductive pattern CL-I may be positioned lower than the insulating pattern SP. In other words, the portion, which is in the non-overlap state with the insulating pattern SP, of the preliminary conductive pattern CL-I may have a thickness thinner than that of the insulating pattern SP. According to an embodiment, the portion, which is in the non-overlap state with the insulating pattern SP, of the preliminary conductive pattern CL-I may have a thickness of about ⅓ of the maximum thickness of the insulating pattern SP.

According to an embodiment of the disclosure, the step of controlling the thickness of the preliminary conductive pattern CL-I before or after the etching process of the preliminary conductive pattern CL-I may be further included. According to another embodiment of the disclosure, the thickness of the preliminary conductive pattern CL-I may be controlled during the deposition process for the preliminary conductive pattern CL-I, or the thickness of the preliminary conductive pattern CL-I may be controlled during the etching process for the preliminary conductive pattern CL-I.

According to the disclosure, the insulating pattern in the signal pad of the display panel may allow the conductive pattern of the signal pad to protrude toward the electronic component. The display panel may be bonded to the electronic component without the anisotropic conductive film, and the short failure may be reduced by the conductive ball. Since the bonding pressure may be reduced, the physical damage to the display panel or the electrical part may be reduced in the bonding process.

According to the disclosure, the signal pad may include the conductive pattern having the mesh form to cover a portion of the insulating pattern. The conductive pattern of the mesh shape may be provided in the form of protrusions protruding from the insulating pattern when viewed in the cross-sectional view. Accordingly, the tensile strength may be more increased in the bonding process through the plurality of protrusions between an insulating pattern and the buffer electrode. Even after the bonding process has been finished, the close contact to the bump electrode may be maintained. Accordingly, the signal pad may be stably and electrically connected to the bump electrode. Accordingly, the display device improved in bonding reliability may be provided.

According to the disclosure, the display device including the signal pad to improve the bonding reliability may be manufactured.

Although an embodiment of the disclosure has been described for illustrative purposes, those skilled in the art will appreciate that various modifications, and substitutions are possible, without departing from the scope and spirit of the disclosure. Accordingly, the technical scope of the disclosure is not limited to the detailed description of this specification.

While the disclosure has been described with reference to embodiments thereof, it will be apparent to those of ordinary skill in the art that various changes and modifications may be made thereto without departing from the spirit and scope of the disclosure.

What is claimed is:

1. A display device, comprising:
a display module including:
a pixel;
a signal line electrically connected to the pixel; and
a signal pad electrically connected to the signal line, wherein
the signal pad includes:
an insulating pattern disposed on the signal line; and
a conductive pattern electrically connected to the signal line,
the conductive pattern includes:
a first part including a mesh pattern; and
a second part surrounding the first part, and
at least a portion of the first part is disposed on the insulating pattern.

2. The display device of claim 1, wherein
the conductive pattern includes a conductive material, and
the insulating pattern includes a polymer.

3. The display device of claim 1, wherein the mesh pattern includes:
first mesh lines extending in a first direction, and disposed in a second direction intersecting the first direction; and
second mesh lines extending in the second direction and disposed in the first direction while intersecting the first mesh lines.

4. The display device of claim 3, wherein
the insulating pattern includes a plurality of insulating patterns,
the first part includes a plurality of first parts, and
each of the plurality of first parts is disposed on a relevant insulating pattern among the plurality of insulating patterns.

5. The display device of claim 3, wherein
the insulating pattern includes a plurality of insulating patterns, and
the first part is disposed on the plurality of insulating patterns.

6. The display device of claim 5, wherein
the plurality of insulating patterns are disposed in the first direction,
each of the first mesh lines intersects the plurality of insulating patterns, when viewed in a plan view,
the second mesh lines include a plurality of line groups, and
each of the plurality of line groups intersects a relevant insulating pattern among the plurality of insulating patterns, when viewed in a plan view.

7. The display device of claim 3, wherein
the insulating pattern includes a plurality of insulating patterns, and
the plurality of insulating patterns are disposed in at least one of the first direction and the second direction.

8. The display device of claim 1, wherein the insulating pattern has a semi-circular shape, when viewed in a cross-sectional view.

9. The display device of claim 1, wherein
the display module further includes a pad insulating layer between the signal line and the conductive pattern, and
the pad insulating layer has a contact hole defined in the pad insulating layer, spaced apart from the insulating pattern, and overlapping a portion of the signal line.

10. The display device of claim 9, wherein
the conductive pattern contacts the signal line through the contact hole, and
the insulating pattern is directly disposed on the pad insulating layer.

11. The display device of claim 10, wherein
the pixel includes:
a light emitting element;
a transistor electrically connected to the light emitting element, and including a semiconductor pattern and a gate overlapping the semiconductor pattern;
an upper electrode disposed on the gate; and
a plurality of conductive layers electrically connected to the transistor, disposed on the upper electrode, and disposed in mutually different layers;
a portion, which is disposed under the conductive pattern, of the signal line and the gate or the upper electrode include a same material, and
the conductive pattern and a material of at least one of the plurality of conductive layers include a same material.

12. The display device of claim 9, wherein
the signal pad further includes a lower conductive pattern disposed under the conductive pattern and contacting the signal line through the contact hole, and
the insulating pattern is between the lower conductive pattern and the conductive pattern.

13. The display device of claim 12, wherein
the pixel includes:
a light emitting element;
a transistor electrically connected to the light emitting element, and including a semiconductor pattern and a gate overlapping the semiconductor pattern;
an upper electrode disposed on the gate; and
a plurality of conductive layers electrically connected to the transistor, disposed on the upper electrode, and disposed in mutually different layers, and
a portion, which is disposed under the conductive pattern, of the signal line and the gate or the upper electrode include a same material.

14. The display device of claim 13, wherein
the lower conductive pattern and at least some conductive layers of the plurality of conductive layers include a same material, and
the conductive pattern and other conductive layers of the plurality of conductive layers, which are disposed on the at least some conductive layers, include a same material.

15. The display device of claim 13, wherein
the display module further includes:
a thin film encapsulation layer disposed on the pixel; and
a sensing electrode disposed on the thin film encapsulation layer,
the lower conductive pattern and at least one conductive layer of the plurality of conductive layers include a same material, and
the conductive pattern and the sensing electrode include a same material.

16. The display device of claim 15, wherein
the display module further includes a sensor insulating layer between the lower conductive pattern and the conductive pattern, and contacting the sensing electrode, and
the conductive pattern contacts the lower conductive pattern through an upper contact hole defined in the sensor insulating layer.

17. A display device, comprising:
a display module including:
a pixel;
a signal line electrically connected to the pixel; and
a signal pad electrically connected to the signal line, wherein
the signal pad includes:
an insulating pattern disposed on the signal line; and
a conductive pattern electrically connected to the signal line, and
at least a portion of the conductive pattern has a form of a plurality of protrusions protruding from the insulating pattern, when viewed in a cross-sectional view.

18. The display device of claim 17, wherein
the at least a portion of the conductive pattern includes:
first mesh lines extending in a first direction, and disposed in a second direction intersecting the first direction; and
second mesh lines extending in the second direction and disposed in the first direction while intersecting the first mesh lines,
the first mesh lines provide the form of the plurality of protrusions, when viewed in a cross-sectional view in the first direction, and
the second mesh lines provide the form of the plurality of protrusions, when viewed in a cross-sectional view in the second direction.

19. A method for manufacturing a display device, the method comprising:
providing a preliminary signal pad including an insulating pattern;
depositing a preliminary conductive pattern on the preliminary signal pad; and
patterning the preliminary conductive pattern to form a conductive pattern at least partially including a mesh pattern,
wherein at least a portion of the mesh pattern is disposed on the insulating pattern.

20. The method of claim 19, wherein the patterning of the preliminary conductive pattern includes:
forming a photoresist pattern on the preliminary conductive pattern;
etching a portion of the preliminary conductive pattern exposed from the photoresist pattern; and
removing the photoresist pattern to form a signal pad.
